(19) United States
(12) Patent Application Publication
(10) Pub. No.: US 2026/0268470 A1
(43) Pub. Date: Sep. 10, 2026

(54) Measurement System, Computer, and Measurement Method

(71) Applicant: Hitachi High-Tech Corporation, Minato-ku, Tokyo (JP)

(72) Inventors: Shinya KYOGOKU, Tokyo (JP); Takahiro NISHIHATA, Tokyo (JP); Mayuka OSAKI, Tokyo (JP); Yasunori GOTO, Tokyo (JP)

(21) Appl. No.: 19/163,699

(22) PCT Filed: Jun. 22, 2023
(86) PCT No.: PCT/JP2023/023182

§ 371 Date: Sep. 9, 2025

(51) Int. Cl. G06T 7/00; G01N 23/203; G01N 23/2206; G01N 23/2251

(52) U.S. Cl. CPC G06T 7/0006; G01N 23/203; G01N 23/2206; G01N 23/2251; G01N 2223/401; G01N 2223/6116; G06T 2207/10056; G06T 2207/20021; G06T 2207/20081; G06T 2207/20221; G06T 2207/30148

(57) ABSTRACT

To provide a technique capable of measuring an overlay deviation amount or the like with high accuracy. In a measurement system, a processor acquires an image (309) of a structure of a semiconductor device captured by a microscope, acquires a measurement area cursor generation rule (308) related to the structure, generates a measurement area cursor to be disposed with respect to the structure based on the image and the measurement area cursor generation rule, disposes the measurement area cursor with respect to the structure in the image, and performs measurement related to the structure using a portion of an image (313) in the measurement area cursor.

### TECHNICAL FIELD

The present disclosure relates to a technique of measuring a dimension, an overlay, or the like of a sample such as a semiconductor.

### BACKGROUND ART

In the related art, regarding a semiconductor pattern measurement device and the like, there is a technique of measuring a dimension, center coordinates, an overlay deviation amount, or the like of a pattern using an image captured by, for example, a scanning electron microscope (SEM) as a type of charged particle beam device. The overlay deviation amount is, for example, an amount of a deviation in an overlap portion between a lower layer pattern and an upper layer pattern.

In recent years, patterns produced by a semiconductor process have undergone miniaturization and have a multilayer structure, and a reduction in amount of pattern misalignment between a plurality of layers in an exposure device is required. Therefore, the importance of measuring the overlay deviation amount with high accuracy and feeding back the overlay deviation amount to the exposure device is increasing.

Examples of means for measuring the overlay deviation amount or the like include a measurement device using the SEM or the like. The SEM generates and outputs a captured image by detecting particles such as secondary electrons and backscattered electrons obtained when a semiconductor wafer or the like as a sample is irradiated with a charged particle beam. The measurement device performs appropriate image processing using the captured image as a measurement target image, and calculates positions of patterns of a plurality of layers to be measured, such as an overlay deviation amount. Accordingly, is it possible to measure the overlay deviation amount or the like.

Examples of the related art include WO2021/038815 (PTL 1) and JP2020-187876A (PTL 2).

### CITATION LIST

### Patent Literature

PTL 1: WO2021/038815
PTL 2: JP2020-187876A

### SUMMARY OF INVENTION

### Technical Problem

PTL 1 discloses that a region divided image is generated based on an input image (measurement target) of a semiconductor having a predetermined structure with reference to a learning model generated based on training data generated from a sample image of the semiconductor and the sample image, and an overlay deviation amount is measured using the region divided image. Here, the training data is an image in which a label including the structure of the semiconductor in the sample image is assigned to each pixel of the image, and the learning model includes a parameter for inferring the training data from the sample image.

PTL 2 discloses that a charged particle beam irradiation unit that irradiates a sample with a charged particle beam, a first detector that detects secondary electrons from the sample, a second detector that detects reflected electrons from the sample, and an image processing unit that generates a first image including an image of a first pattern located on a surface of the sample based on an output of the first detector and that generates a second image including an image of a second pattern located in a lower layer than the surface of the sample based on an output of the second detector are provided, and a control unit measures an overlay deviation amount by adjusting a position of a measurement area cursor in the first image based on a first template image for the first image and adjusting a position of a measurement area cursor in the second image based on a second template image for the second image.

With the miniaturization of the pattern of the semiconductor device or the like, a contour of the pattern appearing in a measurement target image may be unclear. In particular, a boundary where the upper layer pattern and the lower layer pattern overlap and a boundary between the lower layer pattern and a background without the pattern may be unclear. In this case, the measurement accuracy of the overlay deviation amount or the like may decrease.

For example, in the technique of PTL 1, it is difficult to create accurate training data at a pixel level, and when a learning model is trained using erroneous training data, a boundary of a generated region divided image is different from a boundary of an actual pattern. In this case, the measurement accuracy of the overlay deviation amount or the like decreases.

In addition, as the pattern of the semiconductor device is miniaturized and the process is complicated, a process variation amount of individual patterns apart from each other in the measurement target image may be relatively large with respect to a pattern size. In this case, the measurement accuracy of the overlay deviation amount or the like may decrease.

For example, in the technique of PTL 2, the measurement area cursor set in the template image is disposed in the measurement target image. Therefore, when a pattern in the measurement target image fluctuates or varies in size or position as compared with a pattern in the template image, the measurement area cursor may not be disposed at the position of a measurement target pattern. In this case, the overlay measurement accuracy decreases.

Note that, the process variation is as follows. When any fluctuation or variation is generated in a production step (in other words, a process) for a semiconductor device, the fluctuation or variation is reflected in a pattern structure of the produced semiconductor device, and a fluctuation or variation amount of the size or the position in the actual pattern structure is generated. In addition, the actual variation amount also appears as a variation amount of the pattern structure in the measurement target image.

An object of the disclosure is to provide a technique capable of measuring an overlay deviation amount or the like stably, in other words, with accuracy higher than that in the above techniques of measuring the overlay deviation amount or the like.

### Solution to Problem

A representative embodiment of the disclosure has the following configurations. In an embodiment, a measurement system for a semiconductor device includes: a microscope; and a processor, in which the processor acquires an image of a structure of the semiconductor device captured by the microscope, acquires a measurement area cursor generation rule related to the structure, generates a measurement area cursor to be disposed with respect to the structure based on the image and the measurement area cursor generation rule, disposes the measurement area cursor with respect to the structure in the image, and performs measurement related to the structure using a portion of the image in the measurement area cursor.

### Advantageous Effects of Invention

According to a typical embodiment of the disclosure, it is possible to provide a technique capable of measuring an overlay deviation amount or the like stably, in other words, with accuracy higher than that in the above techniques of measuring the overlay deviation amount or the like. Problems, configurations, effects, and the like other than those described above will be made clear in embodiments for carrying out the invention.

### BRIEF DESCRIPTION OF DRAWINGS

FIG. 1 is a diagram showing a configuration of a measurement system according to Embodiment 1.

FIG. 2 is a diagram showing a configuration of a computer as a computer system in Embodiment 1.

FIG. 3 is a functional block configuration diagram of the measurement system according to Embodiment 1.

FIG. 4A is an XY plan view showing an example of a measurement target design structure in Embodiment 1.

FIG. 4B is an XZ cross-sectional view showing the example of the measurement target design structure in Embodiment 1.

FIG. 5 is an XY plan view of a structure when there is a deviation amount with respect to the design structure in FIG. 4A in Embodiment 1.

FIG. 6 is an XY plan view of the structure when there is a fluctuation from the structure in FIG. 5 due to a process variation in Embodiment 1.

FIG. 7A is a schematic diagram of an SE image obtained by capturing the structure in FIG. 6 in Embodiment 1.

FIG. 7B is a schematic diagram of a BSE image obtained by capturing the structure in FIG. 6 in Embodiment 1.

FIG. 8 is a flowchart of processing of a training unit in Embodiment 1.

FIG. 9A is a diagram showing Example 1 of a region divided image of a sample image in Embodiment 1.

FIG. 9B is a diagram showing Example 2 of the region divided image of the sample image in Embodiment 1.

FIG. 10 is a flowchart of processing of setting a measurement area cursor generation rule in Embodiment 1.

FIG. 11A is a diagram showing an example of a rule target region in the region divided image in FIG. 9A in Embodiment 1.

FIG. 11B is a diagram showing an example of a rule target region in the region divided image in FIG. 9B in Embodiment 1.

FIG. 12 is a diagram showing a setting example of the measurement area cursor generation rule in Embodiment 1.

FIG. 13A is a diagram showing a first part of a GUI screen example in Embodiment 1.

FIG. 13B is a diagram showing a second part of the GUI screen example in Embodiment 1.

FIG. 14 is a flowchart of processing in a measurement execution phase in Embodiment 1.

FIG. 15 is a diagram illustrating generation of the region divided image and generation of a measurement area cursor in Embodiment 1.

FIG. 16A is a diagram illustrating edge detection and center of gravity calculation based on a measurement area cursor disposed image in Embodiment 1.

FIG. 16B is a diagram showing an example of an overlay measurement result in Embodiment 1.

FIG. 16C is a diagram showing an example of overlay deviation amount measurement in a Y direction based on the measurement area cursor disposed image in Embodiment 1.

FIG. 16D is a diagram showing an example of overlay deviation amount measurement in an X direction based on the measurement area cursor disposed image in Embodiment 1.

FIG. 16E is a diagram showing another example of center of gravity calculation in a modification of Embodiment 1.

FIG. 17 is a diagram showing an example of disposing measurement area cursors in an image in Comparative Examples (Comparative Example 1 and Comparative Example 2) with respect to Embodiment 1.

FIG. 18 is a functional block configuration diagram of a measurement system according to Embodiment 2.

FIG. 19 is a diagram showing an example of generation of a measurement area cursor based on a region divided image in Embodiment 2.

FIG. 20 is a diagram showing details of measurement area cursor generation in Embodiment 2.

FIG. 21 is a diagram showing an example of edge detection and center of gravity calculation in Embodiment 2.

FIG. 22 is a diagram showing a concept and an example of setting the measurement area cursor in Embodiment 1.

FIG. 23 is a diagram showing a concept and an example of setting the measurement area cursor in Embodiment 1.

FIG. 24 is a diagram showing an example of generation of the measurement area cursor according to a measurement area cursor generation rule when there is a pattern deviation amount in Embodiment 1.

FIG. 25 is a diagram showing an example of measuring a pattern dimension in Embodiment 1.

FIG. 26 is an enlarged view of a measurement area cursor boundary setting field in Embodiment 1.

### DESCRIPTION OF EMBODIMENTS

Hereinafter, embodiments of the disclosure will be described in detail with reference to the drawings. In the drawings, the same parts are denoted by the same reference numerals in principle, and repeated description will be omitted. In the drawings, expressions of components may not represent actual positions, sizes, shapes, ranges, and the like in order to facilitate understanding of the invention, but are not intended to be limited.

For the sake of description, in the case of describing processing executed by a program, a program, a function, a processing unit, and the like may be described as a subject, but a subject of hardware thereof is a processor, or a controller, a device, a computer, a system or the like implemented by a processor. A computer executes processing according to the program read out onto a memory by the processor while appropriately using resources such as the memory and a communication interface. Accordingly, predetermined functions, processing units, and the like are implemented. The processor is implemented by, for example, a semiconductor device such as a CPU/MPU or a GPU. The processing is not limited to software program processing, and can be implemented by a dedicated circuit. The dedicated circuit may be an FPGA, an ASIC, a CPLD, or the like.

The program may be installed as data in a target computer in advance, or may be distributed as data from a program source to the target computer. The program source may be a program distribution server on a communication network, or may be a non-transitory computer-readable storage medium, for example, a memory card or a disk. The program may include a plurality of modules. A computer system may include a plurality of devices. The computer system may include a client server system, a cloud computing system, an IoT system, or the like. Various types of data and information are implemented by a structure such as a table or a list, but are not limited thereto. The expressions such as identification information, identifier, ID, name, and number can be mutually replaced.

### Outline of Embodiment

A measurement system according to an embodiment includes a microscope and a processor. In other words, the microscope is a charged particle beam device, an imaging device, or the like. In other words, the processor is a computer, a computer system, or the like including the processor. The measurement system according to the embodiment is a system that measures a predetermined parameter value such as a pattern dimension or an overlay deviation amount, in other words, a value to be measured, for a sample such as a semiconductor device.

In the measurement system according to the embodiment, for example, in a measurement recipe creation phase, the processor generates, based on a sample image obtained by capturing a pattern of a sample, a region divided image of the sample image, and acquires and sets a measurement area cursor generation rule related to a measurement target pattern based on an operation of checking the region divided image by a user. The measurement area cursor generation rule is a rule for generating a measurement area cursor in a measurement target pattern structure, and can be set by the user on a screen.

In the measurement system, for example, in a measurement execution phase, the processor acquires a measurement target image which is an image obtained by capturing the pattern of the sample using the microscope. The measurement system acquires a measurement target image (in other words, an SEM image) which is an image obtained by capturing a sample such as a semiconductor wafer having a predetermined structure, for example, a three-dimensional pattern structure, using the microscope (for example, an SEM).

The processor in the measurement system generates a region divided image based on the measurement target image. The region divided image is an image obtained by division according to a region for each pattern structure. In an example of the embodiment, the measurement system generates a region divided image based on the measurement target image by unsupervised machine learning.

The processor in the measurement system generates a measurement area cursor based on the measurement target image and the measurement area cursor generation rule, and disposes the measurement area cursor in the pattern structure of the measurement target image. The processor in the measurement system acquires and refers to a measurement area cursor generation rule to be applied according to a region element of the pattern structure, applies the measurement area cursor generation rule to the region divided image (particularly, a designated rule target region) of the measurement target image, and generates a measurement area cursor for the region element of the pattern structure. The processor in the measurement system disposes the measurement area cursor in the measurement target image.

Then, the processor in the measurement system measures a predetermined parameter value such as a dimension or an overlay deviation amount of the pattern structure, in other words, a value to be measured, using a portion of the measurement target image in the measurement area cursor, and stores and outputs a measurement result.

The measurement area cursor generation rule is, for example, a rule for designating and determining a boundary of the measurement area cursor according to a correction value, in other words, a relative relationship or a difference from reference coordinate information in the region element of the pattern structure in the region divided image.

In addition, in the measurement system according to the embodiment, the measurement area cursor generation rule includes a measurement area cursor possibility determination rule as a part thereof. In other words, the measurement area cursor generation rule can be additionally set with the measurement area cursor possibility determination rule. The measurement area cursor possibility determination rule is a rule for determining whether measurement is possible by generating and disposing the measurement area cursor for the region element of the pattern structure. When the measurement area cursor is to be generated by applying the measurement area cursor generation rule to the region divided image, the processor in the measurement system determines whether to generate and dispose the measurement area cursor according to the measurement area cursor possibility determination rule. When the determination result is negative, the processor does not generate and dispose the measurement area cursor.

### Embodiment 1

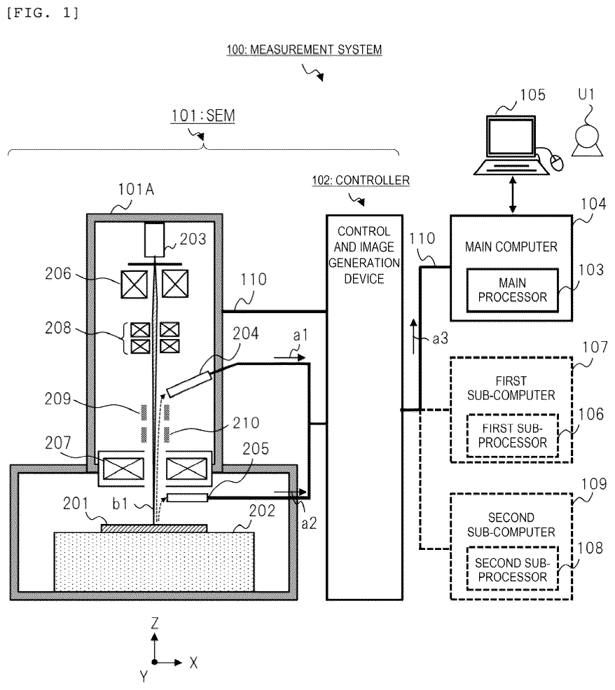

A measurement system and the like according to Embodiment 1 of the disclosure will be described with reference to FIG. 1 and subsequent drawings. The measurement system according to Embodiment 1 is a system in which a computer measures an overlay deviation amount using an image of a semiconductor device captured by a microscope as a measurement target image. A measurement method according to Embodiment 1 is a method to be executed by the computer in the measurement system according to Embodiment 1.

### [Measurement System]

FIG. 1 shows a configuration of a measurement system 100, which is the measurement system according to Embodiment 1. The measurement system 100 includes a scanning electron microscope (SEM) 101, which is a type of charged particle beam device, a main computer 104, an input/output device 105, a first sub-computer 107, and a second sub-computer. The components in FIG. 1 are connected to one another by communication means such as a network 110, for example, a bus, a LAN, a WAN, a cable, and a signal line, and can exchange signals, data, and information as appropriate.

The SEM 101 includes a main body 101A and a controller 102. The SEM 101 captures an image of a pattern (for example, a three-dimensional pattern structure) of a semiconductor 201 (for example, a wafer) as a sample 201, which is an inspection object, and generates and supplies the captured image. The main body 101A irradiates the sample 201 with a charged particle beam b1, and generates and outputs detection signals a1 and a2. The controller 102 is a control and image generation device that controls the entire SEM 101, that drives and controls the main body 101A, and that generates an image, which is a measurement target image, based on the detection signals a1 and a2 from the main body 101A. The controller 102 supplies signal/data a3 such as a captured image to the main computer 104 or the like.

The main computer 104 is a computer connected to the controller 102 and the like and including a main processor 103 as at least one processor. The main computer 104 performs processing of measuring a predetermined parameter value such as a pattern dimension or an overlay deviation amount using the captured image obtained from the SEM 101 as a measurement target image. The main computer 104 stores and outputs measurement result data.

The input/output device 105 is a device to be operated by a user U1 to input instructions, settings, various types of data/information, and the like to the main computer 104 and the like, and output a measurement result and the like. The input/output device 105 includes input devices such as a mouse, a keyboard, and a microphone, and output devices such as a display, a printer, and a speaker. The input/output device 105 may be a client terminal device such as a PC connected via the network 110. The user U1 is a person who performs a measurement work, a management work for the measurement work, or the like using the measurement system.

The main computer 104 or a portion including the main computer 104 and the input/output device 105 is, in other words, one computer system. The computer system may be a client server system in which the main computer 104 is a server and the input/output device 105 is a client. The input/output device 105 may be integrally mounted on the main computer 104.

The first sub-computer 107 and the second sub-computer 109 are sub-computers of the main computer 104. The first sub-computer 107 is a computer connected to the controller 102 and the like and including a first sub-processor 106 as at least one processor. The second sub-computer 109 is a computer connected to the controller 102 and the like and including a second sub-processor 108 as at least one processor. The input/output device 105 may be configured to perform input/output to/from each sub-computer, the input/output device may be provided for each sub-computer, or the input/output device may be integrally mounted on the sub-computer.

In the configuration example in FIG. 1, the main computer 104 performs processing related to overlay measurement (measurement recipe creation processing and measurement processing to be described later) as main processing in the measurement system 100. The first sub-computer 107 or the like, which is a sub-computer, performs processing related to machine learning as sub-processing for assisting the main computer 104. One or more sub-computers are provided. Alternatively, in a modification, the first sub-computer 107 or the second sub-computer 109 may execute the measurement processing. In addition, a plurality of computers (for example, the main computer 104 and a sub-computer, or a plurality of sub-computers) may execute the measurement processing in parallel in a distributed manner.

In the configuration example in FIG. 1, a case where two sub-computers are provided in addition to the main computer 104 is shown, but the disclosure is not limited thereto. In another configuration, only the main computer 104 may be provided, and all arithmetic operations and processing, including measurement and learning, may be executed by the main computer 104. The measurement system 100 only needs to be a system that includes at least one computer system such as the main computer 104, that acquires a measurement target image, and that processes the measurement target image.

In addition, although one SEM 101 is shown in FIG. 1, a plurality of microscopes may be provided, or a server computer or the like that accumulates captured images from an SEM or the like may be used instead of the microscope. When the SEM 101 is a server computer, the server computer stores an image of a semiconductor pattern captured by the SEM in a memory resource such as a storage device, for example, a hard disk drive (HDD). The server computer provides data such as an image in response to a request from the main computer 104 or the like.

In addition, a business operator that manages the main computer 104 or the like that performs the measurement processing as the main processing and a business operator that manages the sub-computer or the like that performs the machine learning may be different from each other. For example, a business operator that manages the main computer 104 may cooperate with a business operator that provides a machine learning service to request a sub-computer that performs machine learning to perform learning or receive a learning result. A sub-computer or the like that performs machine learning may be constructed as a cloud computing system on the Internet.

The main computer 104 executes the measurement recipe creation processing to be described later. A measurement recipe is a series of control information or setting information related to the overlay measurement. In the present embodiment, a part of the measurement recipe also includes information such as a measurement area cursor generation rule for the overlay measurement. In addition, the main computer 104 executes the measurement processing to be described later. The measurement processing is measurement processing for an overlay deviation amount or the like according to the measurement recipe.

Note that, in the case of a client server system, for example, the following operation is performed. The user U1 accesses a server, which is the main computer 104, from a client PC, which is the input/output device 105. The server provides the client PC with a screen having a graphical user interface (GUI). The server transmits GUI screen data (or may be, for example, a web page) therefor to the client PC. The client PC displays the GUI screen on a display based on the received screen data. The user U1 views the GUI screen and inputs instructions, settings, and the like. The client PC transmits the input information to the server. The server executes processing in response to the received input information. For example, the server performs processing of measurement recipe setting and overlay measurement, stores a processing result, and transmits the GUI screen data (or may be only update information) for displaying the processing result to the client PC. The client PC updates the display of the GUI screen based on the received screen data. The user U1 can check the processing result, for example, a measurement recipe or a measurement result, by viewing the GUI screen.

### [SEM]

In FIG. 1, the SEM 101 includes a movable stage 202, which is a sample stage on which the semiconductor 201 which is the sample 201 is to be placed, in the main body 101A including a sample chamber. The movable stage 202 is, for example, a stage that can move in an X direction and a Y direction in the drawing as a radial direction and a horizontal direction, but is not limited thereto, and may be a mechanism that can move in a Z direction, which is a vertical direction, or can rotate or tilt in each axial direction. Although not shown, the main body 101A and the controller 102 also include a drive circuit for driving and controlling the movable stage 202.

The main body 101A includes an electron gun 203, a detector 204, a detector 205, a condenser lens 206, an objective lens 207, an aligner 208, an ExB filter 209, a deflector 210, and the like.

The electron gun 203 generates the charged particle beam b1 with which the sample 201 is irradiated. The condenser lens 206 and the objective lens 207 converge the charged particle beam b1 on a surface of the sample 201. The aligner 208 is configured to generate an electric field for aligning the charged particle beam b1 with respect to the objective lens 207. The ExB filter 209 (ExB: electromagnetic field orthogonal) is a filter for taking secondary electrons emitted from the sample 201 into the detector 204. The deflector 210 is a device for scanning the surface of the sample 201 with the charged particle beam b1.

The detector 204 is a secondary electron detector (in other words, a first detector) that mainly detects secondary electrons (SE) as particles generated from the sample 201, and outputs the detection signal a1. The detector 205 is a backscattered electron detector (in other words, a second detector) that mainly detects backscattered electrons (also referred to as BSE) as particles generated from the sample 201, and outputs the detection signal a2.

The controller 102 receives and inputs the detection signal a1 from the detector 204 and the detection signal a2 from the detector 205, and performs processing such as analog-to-digital conversion on these signals to generate a digital image. The generated image is to be a sample image or a measurement target image. In particular, in the present embodiment, the controller 102 is configured to generate an SE image, which is an image obtained mainly based on secondary electrons, according to the signal a1 from the detector 204, and generate a BSE image, which is an image obtained mainly based on backscattered electrons, according to the signal a2 from the detector 205. The SE image and the BSE image are stored in association with each other.

In the present embodiment, the SEM 101 has a configuration in which the main body 101A has two detection systems of the detector 204 and the detector 205, in other words, two channels, and can generate two types of images, but is not limited thereto, and may be a microscope having one or a plurality of channels.

The controller 102 may be a computer system including a processor, a memory, a communication interface, and the like, or may be a system or a device implemented by a dedicated circuit. The controller 102 temporarily stores the data a3 such as an image generated based on the detection signal in the memory resource. The controller 102 transmits the data a3 such as an image to, for example, the main computer 104 via the communication interface. The main computer 104 receives, inputs, and acquires the data a3 such as an image from the controller 102, and stores the data a3 in its own memory resource. Note that, a memory resource used by a computer such as the main computer 104 may be present as an external storage resource (for example, a database server) on the network 110.

A charged particle beam device/imaging device such as the SEM 101 may have a plurality of channels/systems for detection and imaging. In this example, the SEM 101 has at least two detection channels including SE detection and BSE detection. That is, as described above, two types of images including the SE image and the BSE image can be generated based on the two types of detection signals a1 and a2. In the present embodiment, the controller 102 generates the SE image and the BSE image based on the detection signals a1 and a2, and combines the SE image and the BSE image into one image (referred to as a composite image) by integrating the SE image and the BSE image. Then, the SE image, the BSE image, or the composite image, particularly the composite image in the present embodiment, can be used to generate a region divided image to be described later. As the measurement target image, an SE image, a BSE image, or a composite image can be used and can be selected.

### [Computer System]

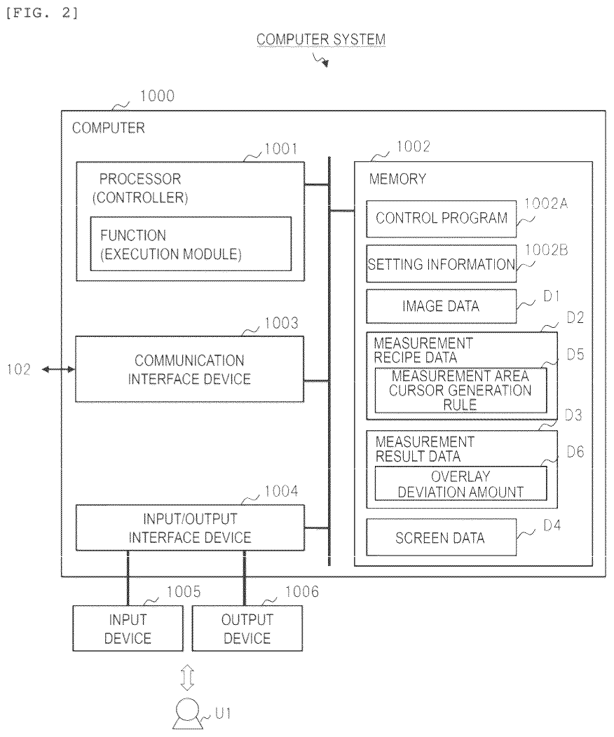

FIG. 2 shows a configuration example of a computer system of a computer such as the main computer 104 in FIG. 1. The computer system in FIG. 2 is mainly implemented by a computer 1000. The computer 1000 includes a processor 1001, a memory 1002, a communication interface device 1003, an input/output interface device 1004, and the like, which are connected to one another via an architecture such as a bus. An input device 1005 and an output device 1006 may be externally connected to the input/output interface device 1004. Examples of the input device 1005 include a keyboard, a mouse, and a microphone. Examples of the output device 1006 include a display, a printer, and a speaker. The input device 1005 and the output device 1006 in FIG. 2 correspond to the input/output device 105 in FIG. 1.

The memory 1002 stores data and information such as a control program 1002A, setting information 1002B, image data D1, measurement recipe data D2, measurement result data D3, and screen data D4. The control program 1002A is a computer program that causes the processor 1001 to execute processing. The setting information 1002B is setting information of the control program 1002A or user setting information. The image data D1 is data of a captured image acquired from the SEM 101. The measurement recipe data D2 is data of a measurement recipe set for overlay measurement. The measurement recipe data D2 includes setting information such as a measurement area cursor generation rule D5. Note that, the measurement recipe may include information such as a capturing condition for causing the SEM 101 to capture an image, or may include the information as another recipe/setting information. The measurement result data D3 is data of an overlay measurement result, and includes information such as an overlay deviation amount D6.

The screen data D4 is data for a GUI screen (for example, a web page) provided to the user U1.

The processor 1001 includes, for example, a CPU, a ROM, and a RAM. The processor 1001 executes processing according to the control program 1002A on the memory 1002. Accordingly, a predetermined function or processing unit of the measurement system 100 is implemented as an execution module. The execution module is implemented during the activation of the computer system.

The communication interface device 1003 is a part that performs communication processing with an external device such as the controller 102 of the SEM 101, another computer, or the input/output device 105 (client terminal) via the network 110 in FIG. 1.

The computer system is not limited to the configuration example in FIG. 2, and may be a system including one or more processors, one or more memories, and the like.

Hereinafter, functions and processing of the measurement system 100 will be described in detail. In Embodiment 1, a case where the overlay deviation amount is set as a value to be measured as the predetermined parameter value will be described. As to be described later, a process of measuring the overlay deviation amount includes measurement of a shape, a dimension, and center coordinates (or center of gravity) of a measurement target pattern based on edge detection of the measurement target pattern. The characteristic concept and function in the disclosure are not limited to the measurement of the overlay deviation amount, and can be similarly applied to the measurement of the shape, the dimension, the center coordinates, and the like of such a pattern.

### [Functional Block Configuration]

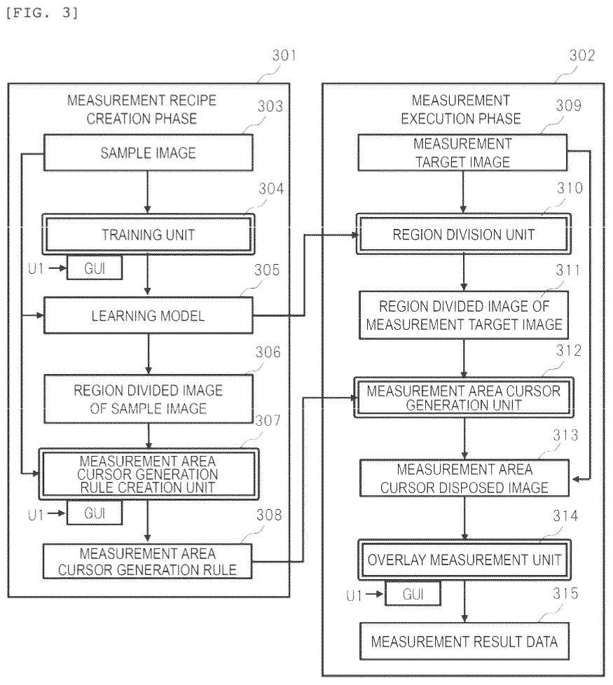

FIG. 3 is a functional block configuration diagram related to processing to be executed in the measurement system 100 according to Embodiment 1. The processing roughly includes a measurement recipe creation phase 301 and a measurement execution phase 302. Note that, the functional block configuration diagram in FIG. 3 may be regarded as a processing flow diagram.

The measurement recipe creation phase 301 is a phase where a measurement recipe related to the target sample 201 is created and set. For example, the main computer 104 in FIG. 1 performs the processing in the measurement recipe creation phase 301. Information about the created measurement recipe is stored in a storage resource in the measurement system 100, for example, a memory in the main computer 104.

The measurement execution phase 302 is a phase where measurement of the overlay deviation amount or the like related to the target sample 201 is executed according to the measurement recipe. For example, the main computer 104 in FIG. 1 performs the processing in the measurement execution phase 302. As a result of this measurement processing, measurement result data including the measured overlay deviation amount or the like is obtained. The measurement result data is stored in the storage resource in the measurement system 100, for example, the memory in the main computer 104.

Note that, various types of data and information such as the measurement recipe, the measurement result, and the system setting information are stored in any storage resource in the measurement system 100. These may be stored, for example, not only in the memory in the main computer 104 but also in a database server or an external storage medium (for example, a memory card) (not shown).

The measurement recipe creation phase 301 includes a training unit 304 and a measurement area cursor generation rule creation unit 307 as main functional blocks. The measurement execution phase 302 includes a region division unit 310, a measurement area cursor generation unit 312, and an overlay measurement unit 314 as main functional blocks. Note that, each of these functional blocks can be implemented by processing on any computer, for example, by program processing by a processor, but is not limited thereto, and may be implemented by a dedicated circuit or the like.

For example, the training unit 304 and the measurement area cursor generation rule creation unit 306 are implemented by the main processor 103 in the main computer 104 reading a corresponding program from a memory (not shown) and executing processing according to the program. The region division unit 306, the measurement area cursor generation unit 312, and the overlay measurement unit 314 are implemented by the main processor 103 in the main computer 104 reading a corresponding program from a memory (not shown) and executing processing according to the program. Alternatively, when a sub-computer performs processing, the functional blocks may be implemented by the sub-processor 106 in the first sub-computer 107 or the sub-processor 108 in the second sub-computer 109 executing processing according to a program.

### [Measurement Recipe Creation Phase]

An outline of the functional blocks in FIG. 3 will be described. First, an outline of the measurement recipe creation phase 301 will be described. Hereinafter, unless otherwise specified, the subject of each processing is a computer or a processor.

The computer inputs a sample image 303. The sample image 303 is an image serving as a sample for training. The training unit 304 inputs the sample image 303, performs training processing, and obtains a learning model 305 as a result of training. The computer obtains a region divided image 306 of the sample image 303 as an output of the learning model 305. That is, the learning model 305 is a model that undergoes machine learning regarding a correspondence relationship between the sample image 303 as an input and the region divided image 306 as an output.

The measurement area cursor generation rule generation unit 307 inputs the region divided image 306 of the sample image 303, performs processing, and obtains a measurement area cursor generation rule 308 as an output. The measurement area cursor generation rule 308 is a rule for generating a measurement area cursor corresponding to the region divided image 306. In the present embodiment, the user U1 checks the region divided image 306 on the screen and sets the measurement area cursor generation rule 308.

The sample image 303 is a sample of a captured image of a pattern as an overlay measurement target collected in advance, in other words, a training image or training data. The learning model 305 is a machine learning model that obtains a region divided image from an image (for example, the sample image 303), and includes parameters such as a coefficient in the machine learning model. The training unit 304 calculates the learning model 305, which outputs the region divided image, based on a pattern structure and density information in the sample image 303. In other words, the parameters of the learning model 305 are adjusted and updated by learning and training. The region divided image 306 of the sample image 303 is an image obtained by inputting, to the learning model 305, the sample image 303 used for calculation by the training unit 304 or another sample image 303 not used for calculation.

The training unit 304 also provides the user U1 with a user interface for performing training. The user interface includes, for example, the GUI screen displayed on the display of the input/output device 105 in FIG. 1. In FIG. 3, the user interface is shown as a “GUI” block. The user U1 appropriately inputs necessary information via the GUI and checks the output information. In the present embodiment, the training unit 304, the measurement area cursor generation rule creation unit 307, and the overlay measurement unit 314 have corresponding GUIs (to be described later) and can perform input and output by the user U1.

The measurement area cursor generation rule creation unit 307 creates and sets, based on a pair of the sample image 303 and the region divided image 306 of the sample image 303, the measurement area cursor generation rule 308 for generating a measurement area cursor to be disposed in the measurement target pattern. At the same time, the measurement area cursor generation rule creation unit 307 also provides the user U1 with a GUI for creating and setting the measurement area cursor generation rule 308.

### [Measurement Execution Phase]

Next, an outline of the measurement execution phase 302 will be described. A computer, for example, the main computer 104, inputs a measurement target image 309 acquired from the SEM 101. The measurement target image 309 is an image of a measurement target such as an overlay deviation amount supplied from the SEM 101 in FIG. 1, particularly, the controller 102, during the overlay measurement.

The region division unit 310 infers a region divided image 311 from the measurement target image 309 with reference to the learning model 305. The region division unit 310 inputs the measurement target image 309 to the learning model 305 that has been sufficient trained, and obtains the region divided image 311 of the measurement target image 309 output as an inference result by the learning model 305.

A measurement area cursor generation unit 313 inputs the region divided image 311 of the measurement target image 309, and generates a measurement area cursor from the region divided image 311 based on reference to the measurement area cursor generation rule 308. Then, the measurement area cursor generation unit 313 generates a measurement area cursor disposed image 313, which is an image in which the generated measurement area cursor is disposed with respect to a measurement target pattern of the measurement target image 309.

The overlay measurement unit 314 inputs the measurement area cursor disposed image 313, measures an overlay deviation amount or the like based on information about a measurement area cursor in the measurement area cursor disposed image 313, and obtains measurement result data 315 including the overlay deviation amount or the like as a measurement result. The overlay measurement unit 314 stores the measurement result data 315 in a memory resource and outputs the measurement result data 315 to a GUI screen.

Basically, the processing of the region division unit 310, the processing of the measurement area cursor generation unit 313, and the processing of the overlay measurement unit 314 can be automatically executed. The details of the overlay measurement method and the like in the overlay measurement unit 314 can be designated by the user U1 on the GUI screen. The user U1 can also select and designate, for example, a dimension, center point coordinates, an overlay deviation amount, or the like as measurement target parameter values on the screen.

### Example of Overlay Measurement Target

Next, an example of the pattern structure of the sample 201 as an overlay measurement target will be described. The overlay deviation amount, which is one of the parameters to be measured, is an amount of a deviation in an overlap portion between an upper layer pattern and a lower layer pattern in a three-dimensional pattern structure of the sample 201.

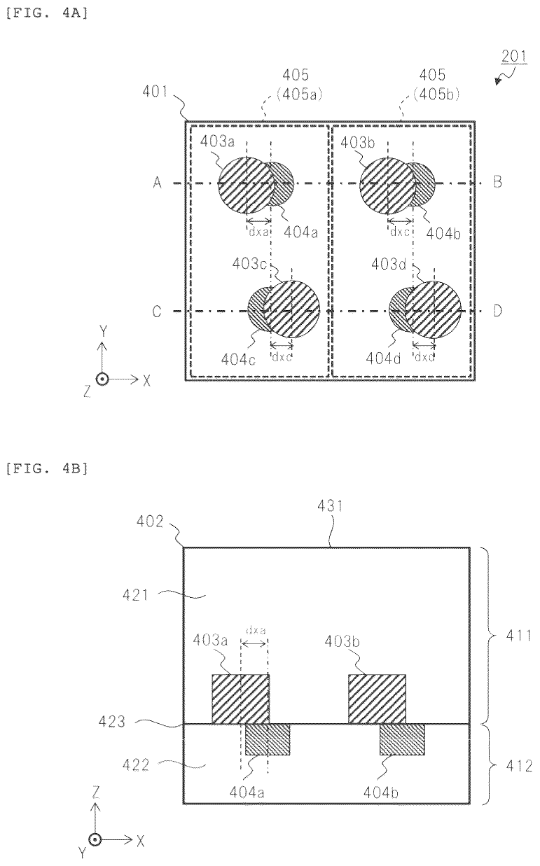

FIG. 4A is an XY plan view of a semiconductor wafer as the sample 201 as the overlay measurement target when viewing an upper surface, in other words, a surface thereof. FIG. 4B is an XZ cross-sectional view showing a design example of a cross-sectional structure corresponding to FIG. 4A. Here, an X axis and a Y axis are two orthogonal axes constituting the upper surface of the semiconductor wafer, and a Z axis is an axis in a height direction/depth direction orthogonal to the X axis and the Y axis. The X axis may be referred to as a horizontal direction, and the Y axis may be referred to as a vertical direction. FIGS. 4A and 4B show a design structure.

A plane region 401 in FIG. 4A is a partial region of the upper surface of the wafer, and in this example, includes eight patterns as schematically shown. The pattern here is a semiconductor structure, and in this example, is a pattern indicated by a circle in an XY plane. Specific examples of the pattern indicated by the circle include a Hall element. A cross-sectional view taken along a line A-B extending in the X-axis direction in FIG. 4A is a cross-sectional structure 402 in FIG. 4B, in other words, the cross-sectional region 402.

In FIG. 4A, an upper layer pattern 403a, an upper layer pattern 403b, an upper layer pattern 403c, and an upper layer pattern 403d in the plane region 401 are patterns formed on the surface of the wafer, i.e., an upper layer 411 in FIG. 4B, in other words, a first layer. These upper layer patterns are visible as circular regions in the XY plane. These upper layer patterns have the same predetermined size, for example, a predetermined diameter.

A lower layer pattern 404a, a lower layer pattern 404b, a lower layer pattern 404c, and a lower layer pattern 404d are patterns formed below the surface of the wafer, i.e., at a position of a lower layer 412 in FIG. 4B, in other words, a second layer. Since these lower layer patterns overlap the upper layer patterns on an upper side and are partially shielded in the XY plane, the lower layer patterns are visible as moon-shaped regions (a shape in which a part of an arc portion of the circle is missing). These lower layer patterns have the same predetermined size, for example, a predetermined diameter, and in this example, have a diameter smaller than the diameter of the upper layer pattern.

In FIG. 4B, the upper layer pattern 403a and the upper layer pattern 403b are formed on a boundary line 423 between the upper layer 411 and the lower layer 412, in other words, on an upper surface of the lower layer 412, and these upper layer patterns are covered with, for example, a region 421 as an insulating film. An upper surface 431 is an upper surface (XY plane) of the region 421 in the upper layer 411. In the lower layer 412, the lower layer pattern 404a and the lower layer pattern 404b are formed below the boundary line 423, and these lower layer patterns are covered with, for example, a region 422 as an insulating film.

In FIG. 4A, a region 405 indicated by a dashed rectangle is a unit cell structure 405, and is an example of a pattern repeatedly formed in the X direction and the Y direction. The structure of the wafer is a structure in which the region 405 as the unit cell structure 405 is repeatedly disposed in a finite number in each of the X direction and the Y direction, including a range not shown. When a unit cell structure 405a is described as a certain unit cell structure 405, it includes the upper layer pattern 403a and the lower layer pattern 404a disposed at a certain position in the Y-axis direction, i.e., a position of the line A-B, and the upper layer pattern 403c and the lower layer pattern 404c disposed at another position in the Y-axis direction, i.e., a position of a line C-D. Similarly, when a unit cell structure 405b is described, it includes the upper layer pattern 403b and the lower layer pattern 404b disposed at the position in the Y-axis direction, and the upper layer pattern 403d and the lower layer pattern 404d disposed at another position in the Y-axis direction.

As shown in the drawings, there is a pair of an upper layer pattern and a lower layer pattern disposed adjacent to each other in the XY plane, which may be referred to as a pattern pair or set. The pattern pair is a pattern structure overlaid in the Z-axis direction, and is a pattern structure in which the upper layer pattern is overlaid on the upper side of the lower layer pattern. In the example in FIG. 4A, there are four pattern pairs in the region 401, and these pattern pairs are disposed apart from each other in the X and Y directions.

In FIG. 4A, the lower layer pattern 404a and the lower layer pattern 404c are designed such that centers of gravity thereof in the X direction coincide with each other, which are indicated by a vertical one-dot chain line. The lower layer pattern 404b and the lower layer pattern 404d are designed such that centers of gravity thereof in the X direction coincide with each other, which are indicated by a vertical one-dot chain line. In addition, the upper layer pattern 403a and the lower layer pattern 404a are designed such that centers of gravity thereof in the Y direction coincide with each other, which are indicated by the line A-B. The upper layer pattern 403c and the lower layer pattern 404c are designed such that centers of gravity thereof in the Y direction coincide with each other, which are indicated by the line C-D. The center of gravity is, for example, a center point of the circle.

Since such a unit cell structure 405 is repeated in the X direction, in the plane region 401, for example, center of gravity Y coordinates of the upper layer pattern 403a, the lower layer pattern 404a, the upper layer pattern 403b, and the lower layer pattern 404b coincide with each other. Center of gravity Y coordinates of the upper layer pattern 404c, the lower layer pattern 404c, the upper layer pattern 404d, and the lower layer pattern 403d coincide with each other.

In addition, in the unit cell structure 405, for example, in the unit cell structure 405a, a difference dxa between center X coordinates of the upper layer pattern 403a and center X coordinates of the lower layer pattern 404a and a difference dxc between center coordinate X coordinates of the upper layer pattern 403c and center X coordinates of the lower layer pattern 404c are designed to have opposite signs and the same absolute value. The same applies to a difference dxc and a difference dxd in the unit cell structure 405a, and dxa=dxc and dxc=dxd in design.

For example, in the unit cell structure 405a, the upper layer pattern 403a overlapping above the lower layer pattern 404a is disposed to be deviated leftward (−X) in the X direction, and the upper layer pattern 403c overlapping above the lower layer pattern 404c is disposed to be deviated rightward (+X) in the X direction. These deviations are correct deviations and displacements in design. Due to these overlaps, in the XY plan view in FIG. 4A, only a part of the circle of the upper surface (a moon shape in which a left arc portion is missing) is visible in the lower layer pattern 404a, and only a part of the circle of the upper surface (a moon shape in which a right arc portion is missing) is visible in the lower layer pattern 404c. The same applies to the unit cell structure 405b, for example.

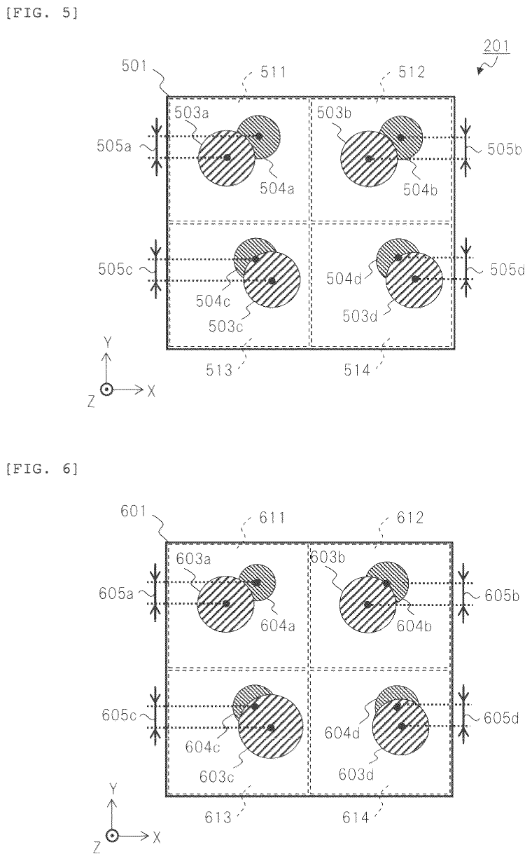

FIG. 5 is an XY plan view showing an example in which there is an overlay deviation amount with respect to the design example in FIG. 4 (FIGS. 4A and 4B). The overlay deviation amount is, for example, an undesirable difference or variation amount with respect to a design value (FIG. 4A) generated by some factor in a semiconductor production process, for example, a process variation larger than a certain degree.

In FIG. 5, a plane region 501 corresponds to the plane region 401 in FIG. 4A. In FIG. 5, as an example of an overlay deviation, a case where each pattern has a positional deviation in the X and Y directions as a whole is shown. An upper layer pattern 503a, an upper layer pattern 503b, an upper layer pattern 503c, and an upper layer pattern 503d are patterns formed on the surface of the wafer, i.e., the upper layer 411 described above, and correspond to the upper layer patterns 403a to 403d in FIG. 4A. A lower layer pattern 504a, a lower layer pattern 504b, a lower layer pattern 504c, and a lower layer pattern 504d are patterns formed below the surface of the wafer, i.e., at the position of the lower layer 412 described above, and correspond to the lower layer patterns 404a to 404d in FIG. 4A.

Note that, for the sake of description, for each pattern pair including an upper layer pattern and a lower layer pattern that are adjacent to each other and vertically overlap in the XY plane, rough regions of each pattern pair are indicated by regions 511 to 514.

In the example in FIG. 5, the lower layer patterns 504a to 504d are formed at positions deviated upward (+Y) in the Y direction from the design positions as shown in FIG. 4A with respect to the upper layer patterns 503a to 503d. That is, the plane region 501 in FIG. 5 has an overlay deviation amount in the Y direction. The overlay deviation amount in the Y direction is measured between the upper layer pattern and the lower layer pattern adjacent to each other. In this example, the overlay deviation amount in the Y direction is a difference between a Y coordinate of a center of gravity of the upper layer pattern (indicated as a center point of the circle) and a Y coordinate of a center of gravity of the lower layer pattern (indicated as a center point of the circle), as shown in the drawing. For example, in a certain region 511, an overlay deviation amount 505a in the Y direction is a value obtained by subtracting a center Y coordinate of the upper layer pattern 503a from a center Y coordinate of the lower layer pattern 504a. Similarly, overlay deviation amounts 505b, 505c, and 505d in the Y direction in the respective regions are values obtained by subtracting center Y coordinates of the upper layer patterns 503b, 504c, and 504d from center Y coordinates of the lower layer patterns 504b, 504c, and 504d, respectively. In FIG. 5, the center point (X coordinate, Y coordinate) of the circle corresponding to the center of gravity is indicated by a black circle point.

Note that, the position of the center of gravity shown in FIG. 5 is conceptual, and the position of the center of gravity cannot always be accurately or easily calculated from the image during measurement. In an example in the related art, there is a case where the position of the center of gravity cannot be accurately obtained from such a pattern pair including an upper layer and a lower layer, in particular, the moon shape of the lower layer pattern. The reason is that, since a boundary of a pattern may be unclear or a process variation amount may be large, an edge of the region may not be detected with high accuracy and the center of gravity may not be calculated with high accuracy in a method of setting a measurement area cursor as in example in the related art.

In this example, the lower layer patterns 504a to 504d are formed at positions deviated rightward (+X) in the X direction from the design positions as shown in FIG. 4A with respect to the upper layer patterns 503a to 503d. That is, there is also an overlay deviation amount in the X direction. However, in the present embodiment, the overlay deviation amount in the X direction is not a measurement target. Hereinafter, a case where the overlay deviation amount in the Y direction, that is, the overlay deviation amount in the Y direction such as the overlay deviation amounts 505a to 505d in FIG. 5 is measured will be described. The measurement system 100 has a function of easily measuring, with high accuracy, such an overlay deviation amount to be measured.

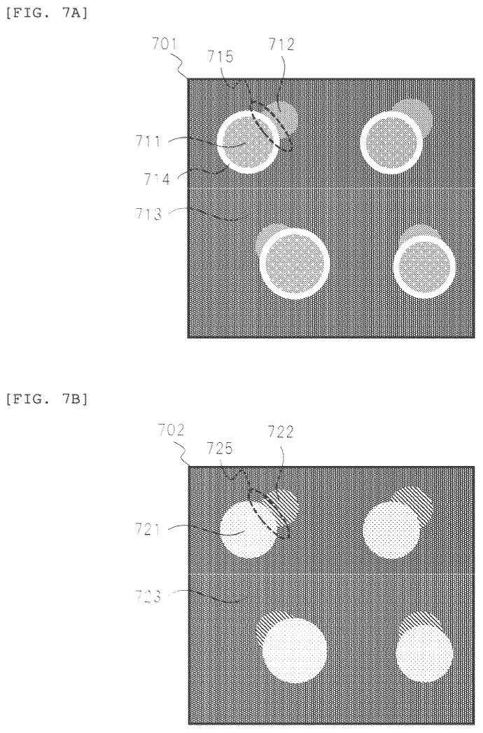

Further, FIG. 6 is an XY plan view showing a case where a size or a position of each pattern is deviated from those in FIG. 5 due to the influence of the process variation. That is, FIG. 6 shows a second example in which there is an overlay deviation amount. The process variation may be a variation not intended by the manufacturer, an intended parameter change in a production process, or the like.

In FIG. 6, in a plane region 601 (including regions 611 to 614), an upper layer pattern 603a, an upper layer pattern 603b, an upper layer pattern 603c, and an upper layer pattern 603d are patterns formed on the surface of the wafer, and a lower layer pattern 604a, a lower layer pattern 604b, a lower layer pattern 604c, and a lower layer pattern 604d are patterns formed at the position of the lower layer of the wafer.

A size of the lower layer pattern 604a, i.e., a diameter of a circle in this example, is smaller than that of the lower layer pattern 504a. The lower layer pattern 604b is formed at a position deviated leftward (−X) in the X direction with respect to the lower layer pattern 504b. A size of the upper layer pattern 603c, i.e., a diameter of a circle in this example, is larger than that of the upper layer pattern 503c. The upper layer pattern 604d is formed at a position deviated rightward (+X) in the X direction with respect to the upper layer pattern 504d.

As in this example, the process variation amount of individual patterns apart from each other in the measurement target image, for example, patterns of the regions 611 to 614, may be relatively large with respect to a pattern size. For example, any fluctuation or variation generated in a wafer production process is reflected in a pattern structure of an actual wafer, and the variation amount of the size, the position, or the like of each pattern is generated as in the example in FIG. 6. Accordingly, overlay deviation amounts 605a to 605d are particularly generated. Such a variation amount of the actual object also appears as a variation amount of the pattern in the measurement target image. In this case, the measurement accuracy of the overlay deviation amount or the like may also decrease.

### [Sample Image and SEM Image]

The sample image 303 in FIG. 3 is an image captured before the measurement of the overlay deviation amount is operated, and is a captured image of the wafer 201 as an overlay measurement target, or a captured image of a wafer close to the captured image of the wafer 201 as an overlay measurement target. Note that, the sample image 303 may be captured by the SEM 101 that operates the overlay measurement, or may be captured and collected by a microscope such as another SEM whose image quality is close to that of the SEM 101.

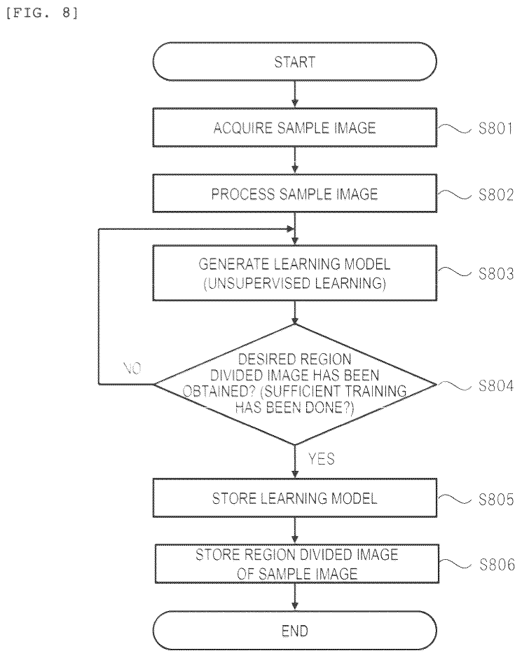

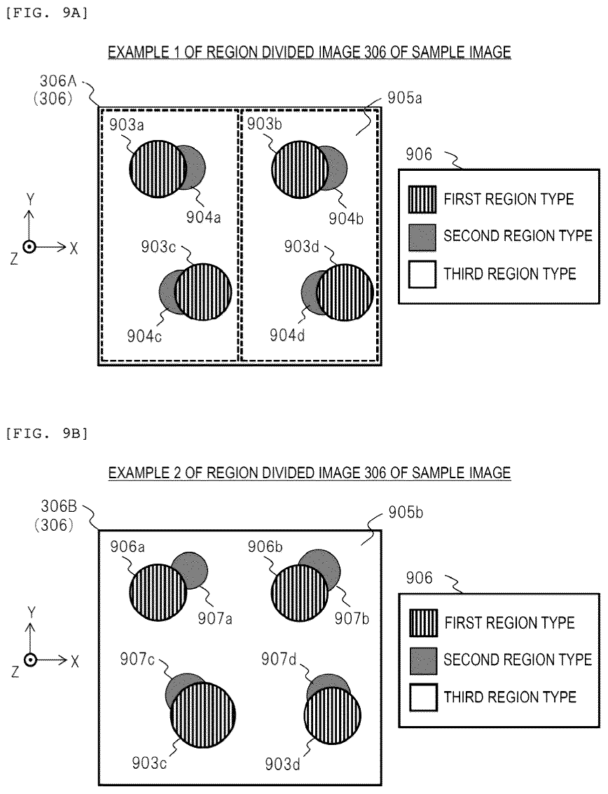

FIG. 7 (FIGS. 7A and 7B) is an example of an SEM image when an image of the structure of the wafer 201 as in the example in FIG. 6, in other words, the actual object, is captured by the SEM 101. An image 701 in FIG. 7A is an SE image 701 obtained based on the signal a1 from the detector 204 described above, and an image 702 in FIG. 7B is a BSE image 702 obtained based on the signal a2 from the detector 205 described above. The sample image 303 includes one or more pairs of the SE image 701 and the BSE image 702. Various images may be obtained as a set of a plurality of images by repeatedly capturing the same pattern region a plurality of times, or may be images obtained by integrating a plurality of images.

Note that, although an actual image has multiple tones, FIG. 7A or the like shows a schematic diagram using several filled pattern regions. In the SE image 701 in FIG. 7A, for example, a region 711 is a region corresponding to the upper layer pattern, and a circular boundary (for example, an edge region 714) appears relatively clear and bright, and thus is shown as a white ring. For example, a region 712 is a region corresponding to the lower layer pattern and appears relatively dark because it is in the lower layer in the Z direction. In addition, a background region 713 appears the darkest.

Note that, the edge region 714 may be divided as a region different from the region in the upper layer pattern due to a brightness difference or the like at the time of generating a region divided image to be described later. For example, the upper layer pattern may be divided into two regions, that is, a circular region and a ring-shaped edge region 714 on an outer periphery of the circular region. Even in such a case, the functions in the embodiment can be similarly applied by selecting an appropriate region type when setting the measurement area cursor generation rule 308. In addition, by imparting an identifier to each of the two or more regions as a region type representing the upper layer pattern, the function in the embodiment can be similarly applied.

Similarly, in the BSE image 702 in FIG. 7B, for example, a region 721 is a region corresponding to the upper layer pattern and appears relatively clear and bright. The region 721 has a brightness higher than a brightness of the region 711 in FIG. 7A. For example, a region 722 is a region corresponding to the lower layer pattern and appears relatively dark because it is in the lower layer in the Z direction. The region 722 has a brightness higher than a brightness of the region 712 in FIG. 7A. The reason is that the BSE is easier to capture the structure of the lower layer than the SE. In addition, a background region 723 appears the darkest. In general, the SE includes a large amount of information about a sample surface, and the BSE includes a larger amount of internal information than the information about the sample surface.

In the SE image 701 in FIG. 7A, for example, when attention is paid to a boundary region 715 between the region 711 and the region 712, since there is a relatively bright edge region 714, a boundary between the region 711 and the region 712 is easy to understand. On the other hand, in the BSE image 702 in FIG. 7B, for example, when attention is paid to a boundary region 725 between the region 721 and the region 722, since a brightness difference between the region 721 and the region 722 is relatively small, a boundary between the region 721 and the region 722 is unclear as compared with FIG. 7A. In other words, a boundary line between the region 721 and the region 722 is unclear. In this manner, the boundary between the upper layer pattern and the lower layer pattern may be unclear in the image. In this case, for example, since it is difficult to clearly detect the region in the lower layer pattern and it is difficult to calculate the center of gravity with high accuracy, it is more difficult to measure the overlay deviation amount.

In addition, in FIG. 7A, for example, since a brightness difference in a boundary between the region 712 in the lower layer pattern and the background region 713 is relatively small, the boundary between the region 712 and the region 713 may be unclear as compared with FIG. 7B. In this case, it is also more difficult to measure the overlay deviation amount.

As in the above example, the boundary of the pattern may be unclear in the measurement target image of the wafer 201. In particular, a boundary where the upper layer pattern and the lower layer pattern overlap may be unclear. In this case, the measurement accuracy of the overlay deviation amount or the like may decrease due to the influence of the process variation. In contrast, in the embodiment, it is possible to cope with this by setting a suitable measurement area cursor generation rule.

### [Training Unit]

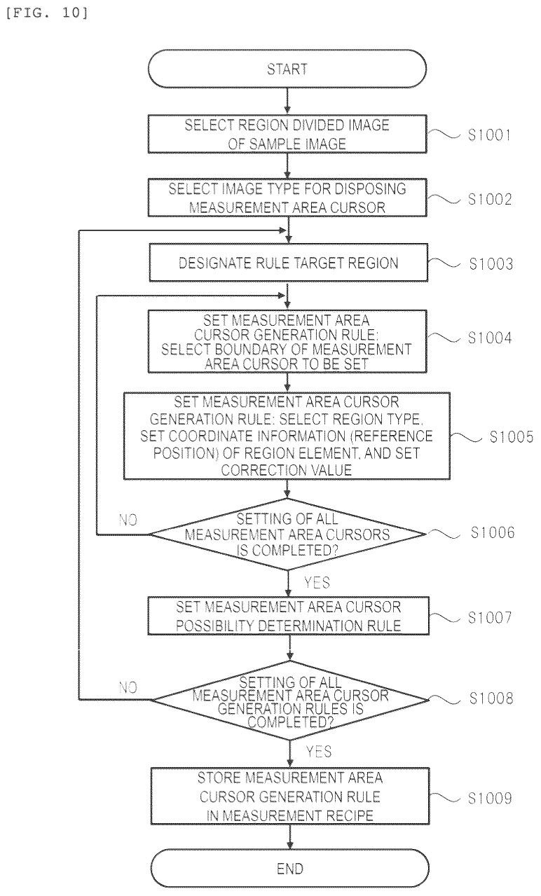

FIG. 8 is a flowchart illustrating processing in which the training unit 304 in FIG. 3 generates the learning model 305. Here, the main computer 104 performs the training processing, but the sub-computer may perform the training processing as described above.

In step S801, the training unit 304 acquires the sample image 303, for example, the SE image 701 as shown in FIG. 7A and the BSE image 702 as shown in FIG. 7B. In step S802, the training unit 304 performs known processing such as adjustment of a contrast of each of the SE image 701 and the BSE image 702 and integration in a direction of (R, G, B) to obtain a suitable pair of the SE image 701 and the BSE image 702. In Embodiment 1, in the training for generating the region divided image 306, a composite image of the SE image and the BSE image is particularly used as a designated image type for the input sample image 303.

In step S803, the training unit 304 first sets an initial value of a coefficient that is a parameter of the learning model 305, and then generates the learning model 305 by calculating the learning model 305 such that a region divided image can be inferred based on the structure and the brightness feature in the image when the sample image 303 is input.

In this manner, a method of calculating a learning model that generates a region divided image by using only an image without a user-specified label for each pixel in an image, in other words, a method of generating a region divided image by unsupervised learning can be implemented by, for example, a technique in the following known literature.

Ji, Xu, Joao F. Henriques, and Andrea Vedaldi. “Invariant information clustering for unsupervised image classification and segmentation.” Proceedings of the IEEE/CVF International Conference on Computer Vision. 2019.

In the present embodiment, the known technique in the above literature is applied to the generation of the region divided image 306. In this case, for example, data input to the learning model 305 by a convolutional neural network (CNN) is a composite image from the SEM 101, and output data has a region type for each pixel.

Thereafter, in step S804, it is determined whether the learning model 305 capable of obtaining a desired region divided image in which a region corresponding to each pattern of the overlay measurement target in the sample image 303 can be divided is obtained. In other words, it is determined whether a sufficient trained learning model 305 is obtained.

When the region corresponding to the measurement target pattern in the sample image 303 is divided in the generated region divided image (YES), in step S805, the training unit 305 stores the generated learning model 305 in a storage resource (not shown), for example, the memory in the main computer 104 in FIG. 1.

Finally, in step S806, the training unit 304 stores the region divided image 306 of the sample image 303 obtained in the above calculation process in a storage resource (not shown), for example, the memory in the main computer 104 in FIG. 1.

Note that, in the present embodiment, as described above, the unsupervised learning is applied to the training unit 304. Without being limited thereto, supervised learning may be applied to the training unit 304. The training unit 304 may perform training using training data that is an image in which a label including a pattern structure in a semiconductor device in a sample image (not shown) is assigned to each pixel of the image.

Instead of the machine learning model, a method of separating the pattern of each layer by setting a threshold value for separating each distribution based on a gray value histogram of the sample image may be applied to the training unit 304.

### [Region Divided Image]

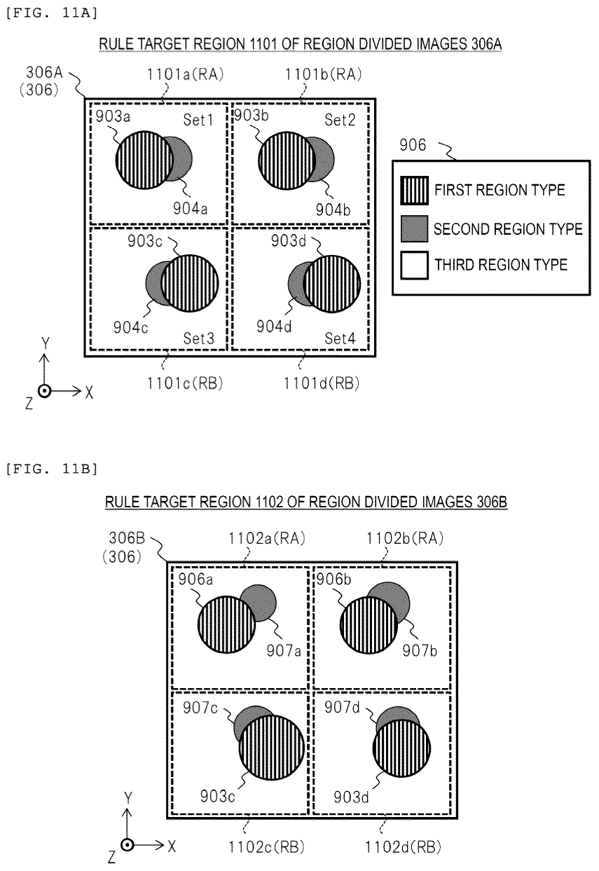

FIG. 9 (FIGS. 9A and 9B) shows two examples, i.e., the region divided image 306 of the sample image 303 output by the training unit 305 in FIG. 3 and the region divided image 306 of the sample image 303 output by the learning model generation in step S803 in FIG. 8.

FIG. 9A shows a region divided image 306A, which is a region divided image 306 of the sample image 303 obtained by capturing the structure in FIG. 4A by the SEM 101. FIG. 9B shows a region divided image 306B, which is the region divided image 306 of the sample image (the SE image 701 and the BSE image 702) in FIG. 7 corresponding to the example in FIG. 6. In this example, the region divided image 306 has three region types as the types of regions included in the image. A legend 906 shows three region types. A first region type (value=0) is a region corresponding to the upper layer pattern and is shown as a stripe region. A second region type (value=1) is a region corresponding to the lower layer pattern and is shown as a gray region. A third region type (value=2) is a region corresponding to the background and is shown as a white region. Here, contour positions of these region types may not match contour positions of the corresponding patterns.

The region divided image 306A in FIG. 9A includes region elements 903a, 903b, 903c, and 903d, region elements 904a, 904b, 904c, and 904d, and a region element 905a as region elements formed by region division. The region divided image 306B in FIG. 9B includes region elements 906a, 906b, 906c, and 906d, region elements 907a, 907b, 907c, and 907d, and a region element 905b as region elements formed by region division.

In these two examples, for example, the region elements 903a, 903b, 903c, and 903d in the region divided image 306A belong to, for example, the first region type as a region type having the same identifier, and correspond to the region in the upper layer pattern. The region elements 904a, 904b, 904c, and 904d belong to, for example, the second region type as a region type having the same identifier, and correspond to the region in the lower layer pattern. The region element 905a is a region type different from the first region type and the second region type, and corresponds to, for example, the background as the third region type.

### [Measurement Area Cursor Generation Rule Creation Unit]

FIG. 10 is a flowchart illustrating processing in which the measurement area cursor generation rule creation unit 307 in FIG. 3 creates the measurement area cursor generation rule 308. Details of this processing will be described later, and an outline of this processing will be described here. In the present embodiment, since the user U1 performs a setting work, in the following description, the subject of the operation of each step, in other words, a trigger is mainly the user U1, but the subject of the corresponding processing is a computer or a processor, for example, the main computer 104. The main computer 104 executes corresponding processing (for example, setting processing) based on an operation input of the user U1.

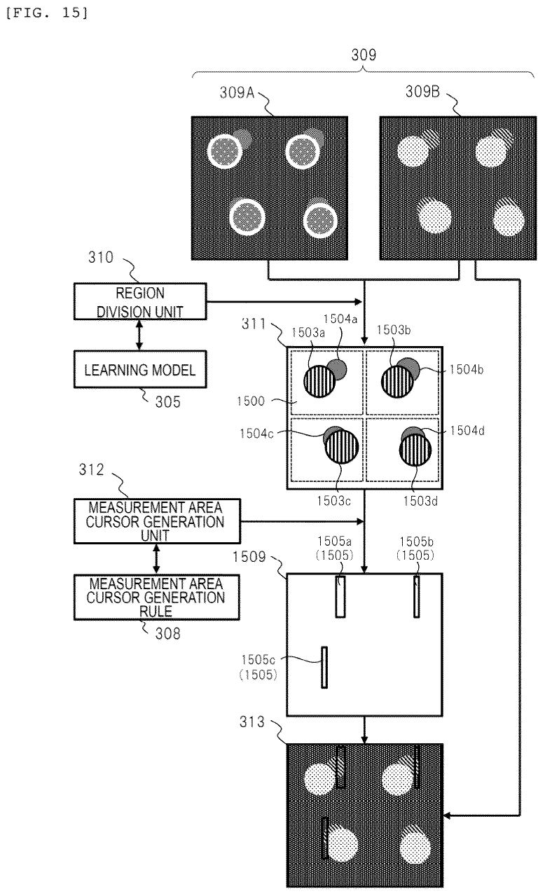

In step S1001, the user U1 selects the region divided image 306 of the sample image 303 stored in a storage resource (not shown), for example, the memory in the main computer 104, via the input/output terminal 105 connected to the main computer 104 in FIG. 3 (a field 1303 in FIG. 13A to be described later). At this time, the selected region divided image 306 and the sample image 303 corresponding to the region divided image 306 are both read. At this time, a measurement target pattern can also be designated.

Next, in step S1002, the user U1 selects, on a screen, an image type for disposing a measurement area cursor (the field 1303 in FIG. 13A to be described later). In the present embodiment, selectable image types include the SE image as shown in FIG. 7A and the BSE image as shown in FIG. 7B. For example, when it is considered to dispose the measurement area cursor with respect to the lower layer pattern, the SE image 701 in FIG. 7A and the BSE image 702 in FIG. 7B have different influences on the measurement, and the user U1 can select, for example, the BSE image 702.

Next, in step S1003, the user U1 designates a rule target region, which is a region to which the measurement area cursor generation rule is to be set, in the region divided image (a field 1304 in FIG. 13A to be described later). At this time, when the measurement area cursor generation rule 308 is common in the sample image, one rule target region in a designated range may be used, and when it is a partial region in the sample image, the rule target region is set for each partial region.

Note that, in step S1003, in the present embodiment, the user U1 freely sets the rule target region including the region element. Examples of a method of setting the rule target region include the following. In a rectangle as one unit cell (FIG. 4A and the like), for example, the unit cell 405a includes four region elements corresponding to a pattern, i.e., the region elements 403a, 404a, 403c, and 404c, and includes, as adjacent patterns, the region elements 403a and 404a as a first pair and the adjacent region elements 403c and 404c as a second pair. The first pair and the second pair are different from each other in a manner that the upper layer pattern and the lower layer pattern overlap each other. In the first pair, the lower layer pattern overlaps the upper layer pattern while being deviated to a position rightward in the X direction. In contrast, in the second pair, the lower layer pattern overlaps the upper layer pattern while being deviated to a position leftward in the X direction. When the application of the measurement area cursor generation rule 308 is considered, it is suitable to apply respective measurement area cursor generation rules for respective pairs having different overlapping manners. Therefore, the user U1 sets a first rule target region including the first pair and a second rule target region including the second pair. In a specific example, the region in the unit cell 405a only needs to be divided into two upper and lower regions.

In the present embodiment, a case where the user U1 sets the rule target region on the screen will be described, but the disclosure is not limited thereto, and the computer may automatically set the rule target region. For example, based on image analysis, learning, or the like, the computer detects region elements other than the background, which are apart from each other in the image, for example, pairs of the upper layer pattern and the lower layer pattern as described above. Then, the computer sets a rule target region for each of the region elements apart from each other.

In step S1004, the user U1 selects a boundary of the measurement area cursor to be set, for setting the measurement area cursor generation rule to be set in the rule target region (a field 1305 in FIG. 13B to be described later).

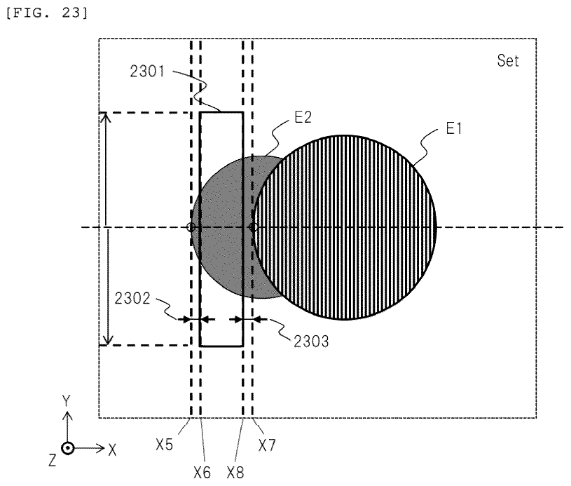

FIG. 22 is a diagram illustrating the measurement area cursor, and is a schematic diagram of an XY plan view when the measurement area cursor is generated and disposed in the region element corresponding to the lower layer pattern in the region divided image. FIG. 22 shows a region element E1 having the first region type corresponding to the upper layer pattern and a region element E2 having the second region type corresponding to the lower layer pattern, which are a pattern pair as one set, and a measurement area cursor 2201 for the region element E2 corresponding to the lower layer pattern. The user U1 designates, on a screen to be described later, a boundary of the measurement area cursor 2201 for measuring the overlay deviation amount in the Y direction with respect to the region element E2 corresponding to the lower layer pattern. In this example, the measurement area cursor 2201 is a rectangle, and four sides of the rectangle, that is, upper, lower, left, and right sides are designated as the boundary. A method of designating the boundary is any, and various known GUIs can be applied. The measurement area cursor 2201 is not limited to a rectangle and may be an elliptical shape or the like.

When the measurement area cursor is, for example, a rectangle, positions of the upper, lower, left, and right sides of the rectangle are sequentially set. For example, the user U1 may designate the positions of the upper, lower, left, and right sides of the rectangle by operating a cursor 2210 (for example, a mouse pointer) on the screen. Alternatively, an upper left point and a lower right point of the rectangle may be designated by clicking or the like. Alternatively, these positions may be input as coordinate values or the like. Alternatively, a center in a left-right direction or a center in an up-down direction of the rectangle may be designated, and a difference amount in the left-right direction or the up-down direction from the center may be designated. A width in the X direction or a width in the Y direction of the rectangle may be designated.

In step S1005, the user U1 selects a region type (for example, a lower layer pattern) used for setting the measurement area cursor generation rule 308 (1305B to be described later). In addition, the user U1 sets coordinate information (in other words, a reference position) of the region element corresponding to the region type (1305C to be described later). In addition, the user U1 sets a correction value of the boundary of the measurement area cursor based on the coordinate information (in other words, the reference position) of the region element (1305C to be described later). In other words, the correction value is a value for determining the boundary of the measurement area cursor based on a relative relationship and a difference from the reference position.

The correction value is, for example, a correction value for determining the boundary as a maximum value or a minimum value of the measurement area cursor in the X direction with a maximum value or a minimum value of the selected region element (for example, the lower layer pattern) in the X direction as reference position coordinates.

Note that, the reference position and the correction value may be as follows. The reference position may be center of gravity coordinates of the selected region element (for example, the lower layer pattern), that is, a rough center of gravity based on the region divided image, and center coordinates of the measurement area cursor may be determined based on the center of gravity coordinates by a desired correction value.

In the example in FIG. 22, for the measurement area cursor 2201, an X coordinate X2 of a right boundary, an X coordinate X4 of a left boundary, a Y coordinate Y1 of an upper boundary, and a Y coordinate Y2 of a lower boundary are set. At this time, first, the Y coordinate Y1 and the Y coordinate Y2 are set, for example, as shown in the drawing, so as to have a size including a width in the Y direction of the region element E2 corresponding to the lower layer pattern. An X coordinate X1 and the X coordinate X2 are designated based on the reference position and the correction value for the region element E2 corresponding to the lower layer pattern.

For the X coordinate of the right boundary, for example, a maximum value in the X direction (in other words, a right end) of the region element E2 corresponding to the lower layer pattern is designated as the reference position. A point at the right end corresponding to the maximum value in the X direction is a point PX1 shown in the drawing, and has the X coordinate X1. For example, “−2 pixels” (two pixels in a left direction in the X direction) is designated as a correction value 2202 from the reference position. In this case, the X coordinate of the right boundary is the X coordinate X2 of a position after moving by two pixels in the left direction as the correction value 2202 from the X coordinate X1 of the point PX1, which is the maximum value in X direction.

In addition, the X coordinate of the left boundary, for example, a maximum value in the X direction (point PX2) of the region element E1 corresponding to the upper layer pattern is designated as the reference position. The point PX2 has an X coordinate X3. For example, “+2 pixels” (two pixels in a right direction in the X direction) is designated as a correction value 2203 from the reference position. In this case, the X coordinate of the left boundary is the X coordinate X4 of a position after moving by two pixels in the right direction as the correction value 2203 from the point PX2, which is the reference position.

In this manner, the measurement area cursor can be determined based on a relative positional relationship with reference to the region element in the region divided image. The user U1 can set the relative positional relationship while checking the region divided image on the screen. In other words, the measurement area cursor generation rule 308 is a rule for generating the measurement area cursor based on the relative positional relationship from the region element in the region divided image. The region element as a reference of the relative relationship may be the measurement target pattern itself (for example, the lower layer pattern) or another adjacent pattern (for example, the upper layer pattern).

In the setting example of the measurement area cursor 2201 in FIG. 22, as the reference position, the right end of the region element E2 corresponding to the lower layer pattern is set as a reference for the right boundary and a right end of the region element E1 corresponding to the upper layer pattern is set as a reference for the left boundary of the measurement area cursor 2201. In addition, in this setting example, at each position in the X direction in the measurement area cursor 2201, the region in the lower layer pattern is included, and the region in the upper layer pattern and the boundary with the upper layer pattern are not included. In addition, a profile in the Y direction does not include a region including only the background portion. Accordingly, an edge of the lower layer pattern can be easily detected by the measurement area cursor 2201, and a variation in size or position of the pattern due to the process variation can also be coped with.

Not limited to the setting example in FIG. 22, for example, the following setting examples are also possible. The region element corresponding to a pattern having a reference position may be only the lower layer pattern or only the upper layer pattern.

In another setting example, a case where the region element corresponding to the pattern having a reference position is only the lower layer pattern is as follows. Similar to the example in FIG. 22, the X coordinate of the right boundary of the measurement area cursor is set, with the right end of the region element E2 corresponding to the lower layer pattern as the reference position. The X coordinate of the left boundary of the measurement area cursor is set, with the maximum value in the X direction (point PX1) of the region element E2 corresponding to the lower layer pattern as the reference position, and for example, “−13 pixels” is designated as the correction value. Accordingly, the left boundary is, for example, the X coordinate X4. In this case, both the left side and the right side of the measurement area cursor are determined based on the relative relationship from the lower layer pattern.

In another setting example, a case where the region element corresponding to the pattern having a reference position is only the upper layer pattern is as follows. Similar to the example in FIG. 22, the X coordinate of the left boundary of the measurement area cursor is set, with the right end of the region element E1 corresponding to the upper layer pattern as the reference position. The X coordinate of the right boundary of the measurement area cursor is set, with the maximum value in the X direction (point PX2) of the region element E1 corresponding to the upper layer pattern as the reference position, and for example, “+13 pixels” is designated as the correction value. Accordingly, the right boundary is, for example, the X coordinate X2. In this case, both the left side and the right side of the measurement area cursor are determined based on the relative relationship from the upper layer pattern.

Each setting example as described above can be selected according to whether a boundary between patterns in an image is clear or unclear. For example, when the boundary between the upper layer pattern and the lower layer pattern is unclear and the boundary between the lower layer pattern and the background region is clearer in the image, the right side and the left side of the measurement area cursor may be determined with the right end or the like of the region element E2 corresponding to the lower layer pattern as a reference position such that the boundary between the upper layer pattern and the lower layer pattern is not used as a reference. Conversely, for example, when the boundary between the lower layer pattern and the background region in the image is unclear, the right side and the left side of the measurement area cursor may be determined with the right end or the like of the region element E1 corresponding to the upper layer pattern as a reference position such that the unclear boundary is not used as a reference.

As in the above example, the measurement area cursor generation rule 308 can be set so as to avoid a portion that may be unclear on the image, and thus, more suitable measurement can be performed.

Return to FIG. 10. In step S1006, it is determined whether the setting of all the measurement area cursors related to the rule target region is completed. When the setting of all the measurement area cursors is completed (YES), the user U1 sets a measurement area cursor possibility determination rule in step S1007 (a field 1306 in FIG. 13B to be described later). Here, the measurement area cursor possibility determination rule refers to a rule that the measurement area cursor is not set when it is calculated and determined, based on the coordinate information of the region element of the region divided image, that the measurement of the measurement target pattern is not possible. In other words, the measurement area cursor possibility determination rule is a rule that the measurement area cursor is not generated in a case where a predetermined condition that makes the measurement impossible is satisfied when the measurement area cursor is to be generated according to the measurement area cursor generation rule 308. The predetermined condition is, for example, a condition that a width of the measurement area cursor is less than a predetermined value.

In step S1008, it is determined whether the setting of all measurement area cursor generation rules 308 related to the measurement target pattern in all rule target regions is completed. When the setting is completed (YES), the computer stores the set measurement area cursor generation rule 308 as a part of the measurement recipe in step S1009.

### [Rule Target Region]

FIGS. 11A and 11B show setting examples of a rule target region 1101 and a rule target region 1102 using the region divided images 306 (306A and 306B) of the sample image 303 shown in FIGS. 9A and 9B as an example. FIGS. 11A and 11B show a case where the rule target region is set in the region divided image 306 by the above method (step S1003 in FIG. 10). FIG. 11A shows the rule target region 1101 (1101a, 1101b, 1101c, and 1101d) set in the region divided image 306A, and FIG. 11B shows the rule target region 1102 (1102a, 1102b, 1102c, and 1102d) set in the region divided image 306B.

In this case, in this example, in each of pattern pairs in an upper portion of the region divided image 306, i.e., two sets (Set1 and Set2), a region indicated by a broken line frame including the pattern pair is the first type of rule target region. In addition, in each of pattern pairs in a lower portion of the region divided image 306, i.e., two sets (Set3 and Set4), a region indicated by a broken line frame including the pattern pair is the second type of rule target region. As described above, in the upper pattern pair and the lower pattern pair, since the positional relationship of the overlap portion between the upper layer pattern and the lower layer pattern adjacent to each other is different to the left and right in the X direction, different types of rule target regions are set. In order to identify the type of the rule target region, symbols RA and RB are also imparted.

That is, in the region divided image 306A in FIG. 11A, the rule target region 1101 includes the rule target regions 1101a and 1101b as the first type of rule target region RA, and includes the rule target regions 1101c and 1101d as the second type of rule target region RB. In the region divided image 306B in FIG. 11B, the rule target region 1102 includes the rule target regions 1102a and 1102b as the first type of rule target region RA, and the rule target regions 1102c and 1102d as the second type of rule target region RB.

For example, the rule target region 1101a is a rectangular region including the Set1 as a pattern pair, and includes the region element 903a of an upper layer pattern (first region type) and the region element 904a of a lower layer pattern (second region type). The measurement area cursor generation rule 308 is set for each type of rule target region. A first measurement area cursor generation rule is associated with the rule target region RA, and a second measurement area cursor generation rule is associated with the rule target region RB. For example, in the first type of rule target region RA, the measurement area cursor generation rule 308 for generating the measurement area cursor as shown in FIG. 22 is set. In the second type of rule target region RB, the measurement area cursor generation rule 308 for generating a measurement area cursor for the lower layer pattern disposed leftward in the X direction with respect to the upper layer pattern is similarly set. The measurement area cursor generation rule 308 in this case only needs to be considered by reversing the left and right in the X direction in FIG. 22.

### Example of Measurement Area Cursor Generation Rule

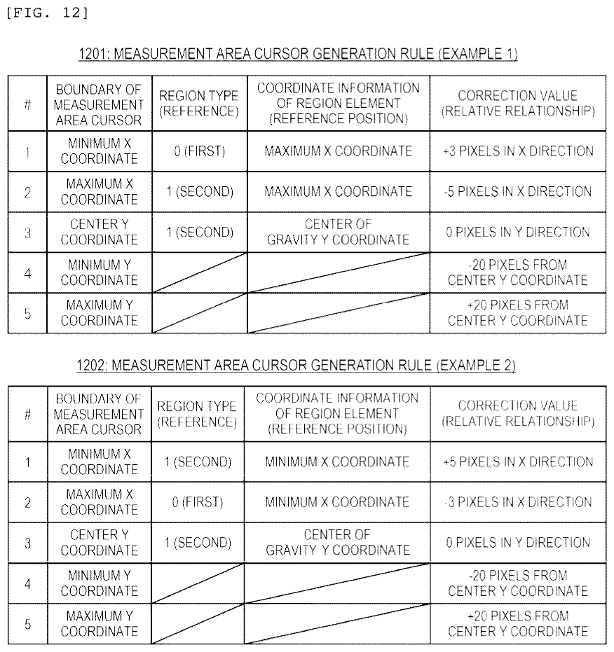

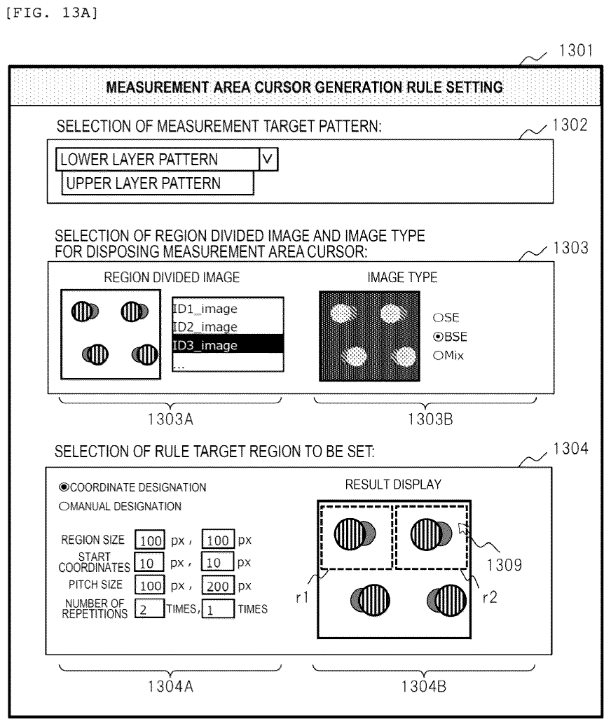

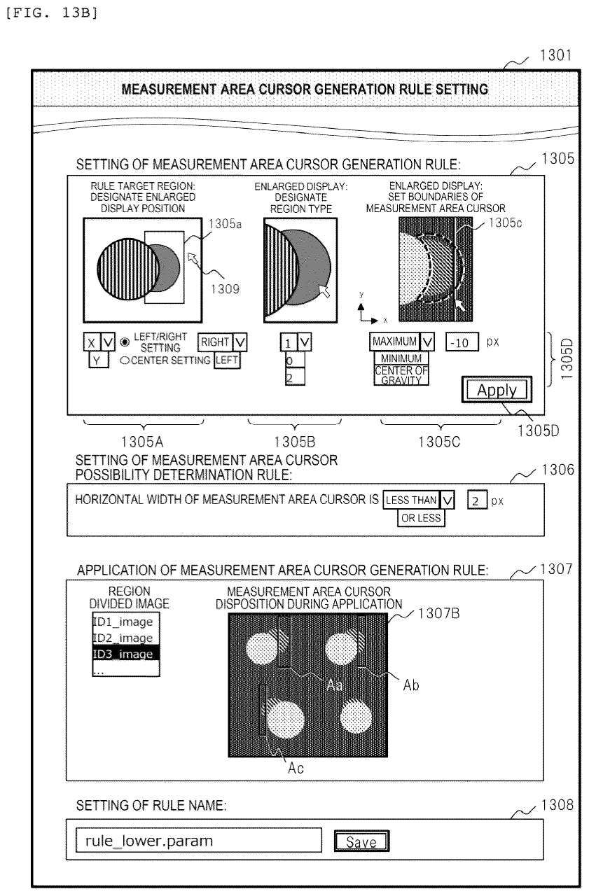

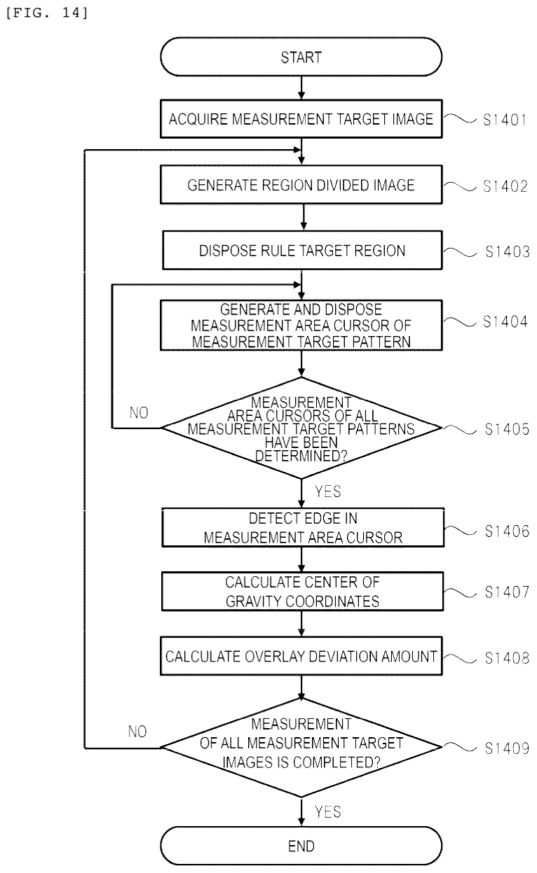

FIG. 12 shows, in a table format, an example of the measurement area cursor generation rule 308 that has been set and stored. The upper table shows a measurement area cursor generation rule 1201 as Example 1, and the lower table shows a measurement area cursor generation rule 1202 as Example 2. The measurement area cursor generation rule 1201 is the measurement area cursor generation rule 308 set for application to the first type of rule target region RA and particularly to the lower layer pattern in FIGS. 11A and 11B. The measurement area cursor generation rule 1202 is the measurement area cursor generation rule 308 set for application to the second type of rule target region RB and particularly to the lower layer pattern in FIGS. 11A and 11B.

The table for the measurement area cursor generation rule 308 includes, for example, “boundary of measurement area cursor”, “region type”, “coordinate information of region element”, and “correction value” as items.

Note that, in the setting of the measurement area cursor generation rule as shown in FIG. 12, although not shown, a correspondence relationship with the measurement area cursor generation rule to be applied is set for each rule target region. An ID is imparted to each rule target region and each measurement area cursor generation rule, and a correspondence relationship therebetween is stored in data management.

The measurement area cursor generation rule 1201 as Example 1 includes five rule elements indicated by rows #1 to #5. When the measurement area cursor is a rectangle, 1. a minimum X coordinate (in other words, a position at the left side), 2. a maximum X coordinate (in other words, a position at the right side), 3. a center Y coordinate, 4. a minimum Y coordinate (in other words, a position at the lower side), and 5. a maximum Y coordinate (in other words, a position at the upper side) are determined as the boundary (or the center) of the measurement area cursor.

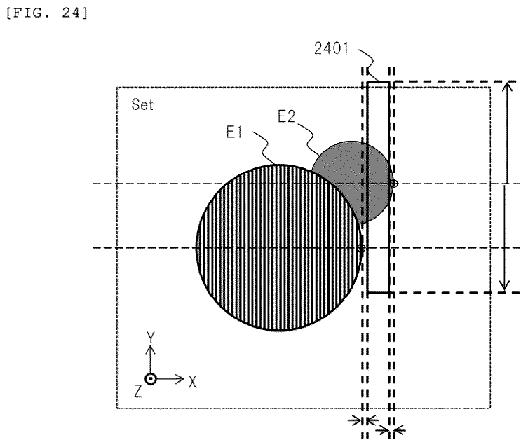

FIG. 22 shows a concept of generating a measurement area cursor 2301 according to the rule elements #1 to #5 in the measurement area cursor generation rule 1201 as Example 1. Similarly, FIG. 23 shows a concept of generation of a measurement area cursor 2302 according to rule elements #1 to #5 in the measurement area cursor generation rule 1202 as Example 2.

The rule element #1 in Example 1 defines the minimum X coordinate (in other words, the position at the left side) as the boundary of the measurement area cursor. The region element as a reference for determining the boundary has a region type of value 0 (first region type). As coordinate information of the region element, the reference position is the maximum coordinate (in other words, the position at the right end), and the correction value (in other words, the relative relationship) is +3 pixels in the X direction from the reference position. The minimum X coordinate is determined as the boundary of the measurement area cursor based on the reference position and the correction value. The rule element #2 determines the maximum X coordinate (in other words, the position at the right side) as the boundary of the measurement area cursor. The region type is value 1 (second region type). The reference position is the maximum X coordinate of the region element. The correction value is-5 pixels in the X direction.

The rule element #3 determines the center Y coordinate as the boundary of the measurement area cursor. The region type is value 1 (second region type). The reference position is the center of gravity Y coordinate of the region element. The correction value is 0 pixels in the Y direction. The rule element #4 determines the minimum Y coordinate (lower side) as the boundary of the measurement area cursor. There is no region type, there is no reference position, and the correction value is −20 pixels from the center Y coordinate. The rule element #5 determines the maximum Y coordinate (upper side) as the boundary of the measurement area cursor. There is no region type, there is no reference position, and the correction value is +20 pixels from the center Y coordinate.

In FIG. 22, a center of gravity Y coordinate Y0 of the region element E2 having the second region type is calculated, and the center of gravity Y coordinate Y0 is the center Y coordinate of the measurement area cursor 2201. The maximum Y coordinate Y1 (upper side B1) of the measurement area cursor 2201 is determined at a position of +20 pixels upward in the Y direction from the center of gravity Y coordinate Y0, and the minimum Y coordinate Y2 (lower side B2) of the measurement area cursor 2201 is determined at a position of −20 pixels downward in the Y direction from the center of gravity Y coordinate Y0. In addition, the maximum X coordinate X3 (the position at the right end) of the region element E1 having the first region type is calculated, and the minimum X coordinate X4 (left side B4) of the measurement area cursor 2201 is determined at a position of +3 pixels (correction value 2203) in the X direction from the reference position. In addition, the maximum X coordinate X1 (the position at the right end) of the region element E2 having the second region type is calculated, and the maximum X coordinate X2 (right side B3) of the measurement area cursor 2201 is determined at a position of −5 pixels (correction value 2202) in the X direction from the reference position.

Similarly, the measurement area cursor generation rule 1202 as Example 2 includes five rule elements indicated by rows #1 to #5. Points different from the rule in Example 1 are as follows. In the rule element #1, the region type is value 1 (second region type), the reference position is the minimum X coordinate (position at the left side), and the correction value is +5 pixels in the X direction. In the rule element #2, the region type is value 0 (first region type), the reference position is the minimum X coordinate (position at the left side), and the correction value is-3 pixels in the X direction.

In FIG. 23, the center Y coordinate, the maximum Y coordinate, and the minimum Y coordinate of the measurement area cursor 2301 are determined in the same manner as in FIG. 22. A minimum X coordinate X5 (a position at the left end) of the region element E2 having the second region type is calculated, and a minimum X coordinate X6 (left side) of the measurement area cursor 2301 is determined at a position of +5 pixels (correction value 2302) in the X direction from the reference position. In addition, a minimum X coordinate X7 (a position at the left end) of the region element E1 having a first region element is calculated, and a maximum X coordinate X8 (right side) of the measurement area cursor 2301 is determined at a position of −3 pixels (correction value 2303) in the X direction from the reference position.

The center of gravity coordinates will be supplementarily described. In the example in FIG. 12, as indicated by #3, the center of gravity Y coordinate of the region element in the region divided image is also used as the reference position. It should be noted that this is different from the center of gravity Y coordinate of the measurement target pattern in the measurement target image to be measured using the measurement area cursor. The center of gravity Y coordinate of the region element is a rough center of gravity coordinate different from an accurate center of gravity coordinate of the lower layer pattern of the measurement target image. The center of gravity Y coordinate of the region element is not accurate, and a tendency of whether the lower layer pattern is deviated upward or downward in the Y direction is shown. Therefore, if the boundary (upper side, lower side) of the measurement area cursor is set by taking correction values up and down using the center of gravity Y coordinate of the region element as a reference, it is possible to fit upper and lower edges of the lower layer pattern within the measurement area cursor with a high probability.

In other words, in Embodiment 1, by setting the measurement area cursor generation rule for generating the measurement area cursor based on the relative relationship with reference to information about the region element of the region divided image as described above, it is possible to cope with a case where it is uncertain where the measurement target pattern is in the measurement target image, and it is possible to generate a suitable measurement area cursor. In the related art, an accurate measurement area cursor cannot be disposed unless it is known where the measurement target pattern is in the measurement target image. In contrast, in Embodiment 1, it is possible to grasp end coordinates, the center of gravity coordinates, and the like of the region element such as the lower layer pattern in the region divided image, generate a suitable measurement area cursor based on the correction value with reference to the rough coordinates, and dispose the measurement area cursor in the measurement target image. Based on the measurement area cursor, the edge and the center of gravity of the pattern can be calculated with higher accuracy than the edge and the center of gravity in the region divided image. Therefore, the measurement accuracy can be improved.

In the setting examples of the measurement area cursor generation rule 308 in FIGS. 22 and 23, the reference position is selected in consideration of being easily detected from the image. The image type of the image for obtaining the reference position can be selected from, for example, the SE image and the BSE image as described above, and it is not necessary to unify the images to one, and a plurality of images can be used separately. In other words, the measurement area cursor generation rule 308 can be set such that the reference position is detected from the image of the image type in which the reference position is easily detected.

FIG. 24 is a diagram illustrating a case where the example of the measurement area cursor generation rule 308 in FIG. 12 is similarly applied to one set of region divided images having a positional deviation as in FIG. 11B. In this case, a measurement area cursor 2401 as shown is obtained. Although a size or a position of the region element E2 corresponding to a lower layer pattern in FIG. 24 varies as compared with those of the region element E2 corresponding to the lower layer pattern in FIG. 22, the measurement area cursor 2401 can capture a region having a suitable profile of the lower layer pattern (a region excluding a boundary with an upper layer pattern and a portion of only a background region), similar to the measurement area cursor 2201. Therefore, the edge of the region in the lower layer pattern can be detected based on the measurement area cursor 2401, and the center of gravity Y coordinate can be calculated.

### [GUI of Measurement Area Cursor Generation Rule Creation Unit]

FIGS. 13A and 13B show an example of a GUI screen for creating and setting the measurement area cursor generation rule 308 by the measurement area cursor generation rule creation unit 307 in FIG. 3. FIG. 13A shows a first part of a “measurement area cursor generation rule setting” screen 1301, and FIG. 13B shows a second part of the screen 1301. In FIG. 13A, the screen 1301 includes a “selection of measurement target pattern” field 1302, the “selection of region divided image and image type for disposing measurement area cursor” field 1303, and the “selection of rule target region to be set” field 1304. In FIG. 13B, the screen 1301 includes the “setting of measurement area cursor generation rule” field 1305, the “setting of measurement area cursor possibility determination rule” field 1306, an “application of measurement area cursor generation rule” field 1307, and a “setting of rule name” field 1308. Note that, a white arrow image is an example of an operation cursor 1309, and the user U1 can move the operation cursor 1309 by operating a mouse or the like.

The field 1302 is a GUI for selecting and setting a measurement target pattern to which the measurement area cursor generation rule 308 to be set is applied in step S1001 in FIG. 10. The field 1303 is a GUI for selecting the region divided image 306 to be representatively used for setting from a plurality of region divided images 306 and selecting an image type as a target for disposing the measurement area cursor in step S1002. The field 1304 is a GUI for designating a rule target region which is a region to which the measurement area cursor generation rule 308 is applied in step S1003. The field 1305 is a GUI for setting the measurement area cursor generation rule 308 in steps S1004 and S1005. At this time, in the field 1305, the region element and the region type in the region divided image 306 are selected, and the coordinates of the upper, lower, left, and right boundaries of the measurement area cursor are set based on the correction value representing the relative positional relationship from n the coordinates (reference position) of the region element.

The field 1306 is a GUI for setting a measurement area cursor possibility determination rule in step S1007. The field 1307 is a GUI that displays a disposition result of the measurement area cursors when the set measurement area cursor generation rule 308 is applied to the measurement target images of different sample images. The field 1308 is a GUI that assigns a name to the set measurement area cursor generation rule 308 and stores the measurement area cursor generation rule 308 in a measurement recipe storage unit.

In FIG. 13A, in the “selection of measurement target pattern” field 1302, for example, a measurement target pattern, in other words, a pattern as a target in which a measurement area cursor is to be generated according to the measurement area cursor generation rule can be selected from a list box. In this example, options include an upper layer pattern and a lower layer pattern.

In a “region divided image” field 1303A on the left side of the “selection of region divided image and image type for disposing measurement area cursor” field 1303, the region divided image 306 can be selected for displaying and checking a content of the region divided image. In an “image type” field 1303B on the right side, an image type for disposing the measurement area cursor can be selected for displaying and checking an image corresponding to the image type. In this example, the options include SE, BSE, and Mix. Mix is a composite image of the SE image and the BSE image.

In the “selection of rule target region to be set” field 1304, in a field 1304A on the left side, selection can be made from “coordinate designation” and “manual designation” as a method of setting the rule target region, and a region size, a start coordinate, a pitch size, and the number of repetitions can be designated. In a field 1304B on the right side, the set rule target region in the region divided image 306 can be displayed and checked as result display. For example, set rule target regions r1 and r2 are displayed by broken line frames.

Note that, on the screen in FIG. 13A or the like, a region of the unit cell as in FIG. 4A or the like described above may be displayed to allow selection.

In FIG. 13B, in the “setting of measurement area cursor generation rule” field 1305, in a field 1305A on the left side, one rule target region selected in the field 1304 is displayed, and an enlarged display region can be designated from within the rule target region. For example, an enlarged display region 1305a is designated. In addition, in a lower portion (field 1305D) of the field 1305A on the left side, selection can be made from the X direction and the Y direction, and selection can be made from “left/right setting” and “center setting”. The selection of the X direction and the Y direction is selection of a rule related to the X direction or a rule related to the Y direction. The “left/right setting” and the “center setting” are selection of a rule related to a left/right or upper/lower position or a rule related to a center position in the selected direction (X or Y). For example, when “left/right setting” is selected, “right” and “left” can be further selected.

In the field 1305B at the center, the enlarged display region designated in the field 1305A is enlarged and displayed, and the region type can be designated from within the enlarged display region. In this example, selection can be made from value 0 (first region type), value 1 (second region type), and value 2 (third region type). In this example, the second region type which is the lower layer pattern is selected.

In the field 1305C on the right side, the user U1 can set the position of the boundary of the measurement area cursor for a region element having the region type designated in the field 1305B in the enlarged display of the image having the image type selected in the same field 1303B. This is the setting as shown in FIG. 22 described above. FIG. 26 to be described later shows an enlarged view in the field 1305C. In a lower portion (field 1305D) of the field 1305C, the coordinate information (reference position) of the region element designated in the field 1305B can be selected from “maximum”, “minimum”, and “center of gravity”. In addition, the correction value from the reference position can be designated by the number of pixels or the like. Alternatively, as shown in the drawing, the user U1 operates a cursor or the like to move, for example, a line 1305c (position in the X direction) to the left or right, thereby checking and designating the correction value and the position of the boundary corresponding thereto. The line 1305c is a GUI corresponding to the designation in the field 1305D in the lower portion. In this example, in a case of determining the right boundary in the X direction for the measurement area cursor, it is designated that the right boundary is determined at a position of −10 pixels (px) from the maximum X coordinate (right end) of the region element having the value 1 region type (second region type) selected in the field 1305B.

When the Apply button 1305D is pressed, the setting of the measurement area cursor generation rule 308 in the field 1305 is stored and applied. As shown in FIG. 12 described above, the setting data of the measurement area cursor generation rule 308 is stored.

In the “setting of measurement area cursor possibility determination rule” field 1306, the measurement area cursor possibility determination rule can be set. For example, a condition of expression such as “horizontal width of measurement area cursor is less than 2 pixels (px)” can be set by varying the number of pixels of the width or a parameter value such as less than/or less.

In the “application of measurement area cursor generation rule” field 1307, any region divided image can be designated, and an image 1307B in a case where the measurement area cursor generation rule 308 set in the field 1305 is applied to the sample image/measurement target image corresponding to the designated region divided image is displayed as “measurement area cursor disposition during application”. Aa, Ab, and Ac are examples of the generated and disposed measurement area cursors. The user U1 can check whether the measurement area cursor generation rule 308 is suitable by viewing the image 1307B. For example, the user U1 can designate another image having a similar pattern structure with respect to the measurement target pattern, apply the measurement area cursor generation rule to the test, view the result, and check whether the rule is suitable.

In the “setting of rule name” field 1308, the measurement area cursor generation rule 308 set on the screen 1301 can be stored with a name.

As described above, according to the present embodiment, the user U1 can designate and input an item that requires user input to set the measurement area cursor generation rule 308 on the GUI screen, and a suitable measurement area cursor generation rule 308 can be set.

FIG. 26 is an enlarged view of the field 1305C of setting the boundaries of the measurement area cursor. In this example, the line 1305c for designating the correction value in the X direction is displayed so as to overlap an enlarged display region 2601 in the designated BSE image. In the field 1305C, a region element 2610 particularly corresponding to the lower layer pattern in the corresponding region divided image is displayed on the enlarged display region 2601 in the designated BSE image so as to overlap by, for example, a broken line expression. For example, the user U1 views the BSE image, moves the line 1305c to the left and right in the X direction, with a position 2602 at the right end of the region element 2610 corresponding to the lower layer pattern as a reference position, and can designate, based on a correction value 2604, an X coordinate 2603 as the boundary (for example, the right side) of the measurement area cursor. In addition, in this example, as shown in the drawing, there is a deviation between a contour of the region element 2610 and the edge of the region in the lower layer pattern of the actual BSE image. The user can also check such a deviation on the GUI screen.

As in the above example, the edge of the pattern structure in the actual image and the contour of the region element in the region divided image do not necessarily match. Even in such a case, in Embodiment 1, it is possible to cope with the case by setting the measurement area cursor generation rule 308 such that a suitable measurement area cursor is obtained on the GUI screen, for example, as shown in FIG. 22 described above. That is, when the profile in the Y direction is viewed at each position in the X direction, the boundary of the measurement area cursor can be designated by adjusting the correction value with the contour of the region element as a reference position such that only the background region and the region in the lower layer pattern are always included in the measurement area cursor in the profile in the Y direction. Alternatively, the boundary of the measurement area cursor can be designated such that a position in the X direction where it is difficult to distinguish the upper layer pattern from the lower layer pattern, or distinguish the lower layer pattern from the background due to the unclear boundary is excluded from the measurement area cursor.

### [Overlay Measurement]

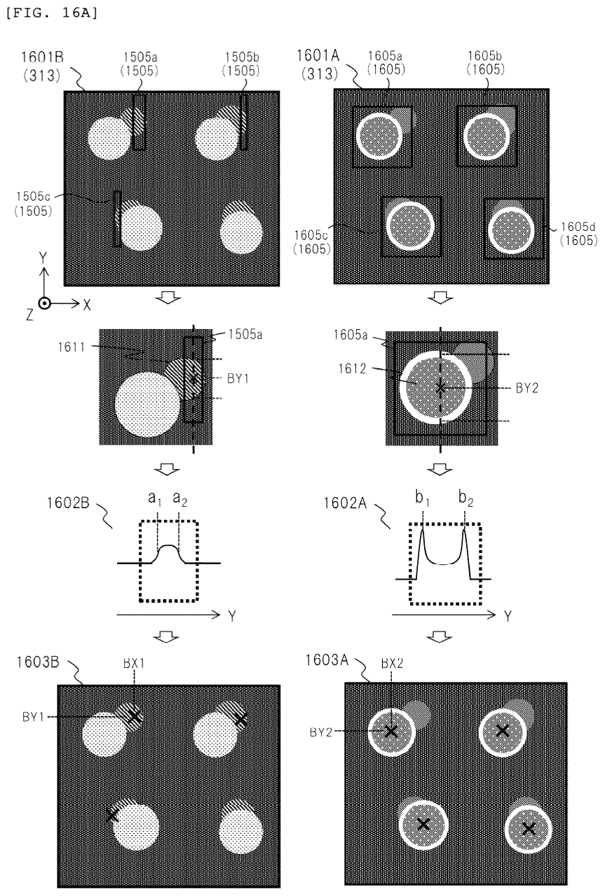

FIG. 14 is a flowchart of the measurement of the overlay deviation amount in the measurement execution phase 302 in FIG. 3. First, in step S1401, the computer, for example, the main computer 104 acquires the measurement target image 309, the SE image as shown in FIG. 7A and the BSE image as shown in FIG. 7B in the present embodiment. At this time, supplementary information such as a position ID is imparted to the measurement target image 309. After the measurement target image 309 is acquired, in step S1402, the region division unit 310 generates the region divided image 311 based on the measurement target image 309 and the learning model 305. Thereafter, first, in step S1403, the computer disposes the rule target region in the region divided image 311. Note that, when the measurement area cursor generation rule 308 is common in the measurement target image 309, step 1403 may be skipped.

Next, in step S1404, the measurement area cursor generation unit 312 in the computer determines the size or the position of the measurement area cursor for measuring each measurement target pattern in the measurement target image 309 based on information about the region divided image 311 and the measurement area cursor generation rule 308, and disposes the generated measurement area cursor in the measurement target image 309. In step S1405, the measurement area cursor generation unit 312 determines whether the measurement area cursors of all the measurement target patterns have been determined in the measurement target image 309. In the case of NO, the processing returns to step S1404 and the same processing is repeated.

After the determination of the measurement area cursor, in step S1406, the overlay measurement unit 314 in the computer detects an edge of the measurement target pattern using a portion of the measurement target image 309 in the measurement area cursor. In step S1407, the overlay measurement unit 314 calculates center of gravity coordinates of the measurement target pattern using the edge coordinates detected in step S1406. In step S1407, the overlay measurement unit 314 calculates the overlay deviation amount related to the measurement target pattern using the center of gravity coordinates. Note that, the measurement is not limited to the overlay deviation amount, and a pattern dimension or the like may be measured. Finally, in step S1408, it is determined whether the measurement of the measurement target patterns of all the measurement target images 309 is completed. In the case of NO, the processing returns to step S1402 and the same processing is repeated.

### [Region Divided Image, Rule Target Region, and Measurement Area Cursor]

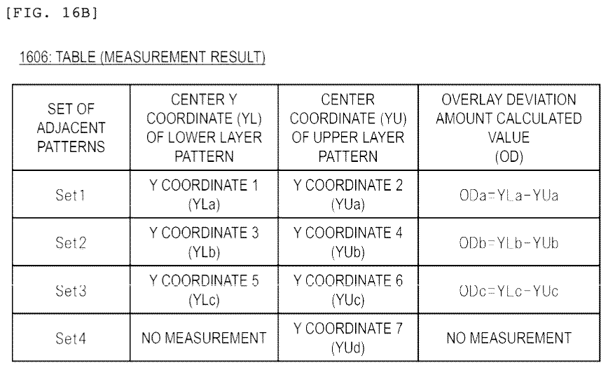

FIG. 15 is a diagram illustrating a specific example of the generation of the region divided image 311 in step S1402, the disposition of the rule target region in step S1403, and the generation and disposition of the measurement area cursor in step S1404 as a generation process in the flow in FIG. 14. FIG. 15 shows, as an example, a case where a measurement area cursor for lower layer pattern measurement is determined.

First, the computer acquires the SE image 309A and the BSE image 309B of the measurement target image 309, and performs image processing same as that in the generation of the learning model 305. The region division unit 310 generates the region divided image 311 of the measurement target image 309 by referring to the learning model 305 stored in a storage unit (not shown).

In the region divided image 311 of the measurement target image 309 in the example in FIG. 15, regions corresponding to the upper layer pattern are region elements 1503a, 1503b, 1503c, and 1503d, and these region elements belong to the same first region type, have a region type same as that of a region element corresponding to the upper layer pattern in the region divided image 306 of the sample image, and have a common identifier. On the other hand, regions corresponding to the lower layer pattern are region elements 1504a, 1504b, 1504c, and 1504d, and these region elements belong to the same second region type, have a region type same as that of a region element corresponding to the lower layer pattern in the region divided image 306 of the sample image, and have a common identifier. In addition, a background region element 1500 also has the third region type same as that of a region element corresponding to the background in the region divided image 306 of the sample image.

After the region divided image 311 is generated, the measurement area cursor generation unit 312 disposes the rule target region (broken line frame in the drawing) in the region divided image 311. The measurement area cursor generation unit 312 generates measurement area cursors 1505a, 1505b, and 1505c for each lower layer pattern as a measurement area cursor 1505 by referring to the measurement area cursor generation rule 308 stored in a storage unit (not shown) for each region element of the rule target region in the region divided image 311.

Here, in the example in FIG. 15, the measurement area cursor generation unit 312 also refers to the measurement area cursor possibility determination rule in the measurement area cursor generation rule 308, and does not generate a measurement area cursor for the lower layer pattern 1504d for the region element 1503d and the region element 1504d as a lower right set. That is, the measurement area cursor generation unit 312 does not generate the measurement area cursor since the measurement area cursor possibility determination rule is not satisfied and it is determined, based on coordinate information of the region element 1503d and the region element 1504d, that upper and lower edges of the lower layer pattern cannot be measured. In the portion of the pattern structure where the measurement area cursor is not disposed, the overlay measurement for a pattern in which accurate edge detection cannot be performed can be excluded.

In the example in FIG. 15, the BSE image 309B is selected as the image type used for lower layer pattern measurement. The measurement area cursor generation unit 312 generates the measurement area cursor disposed image 313 by applying and disposing these measurement area cursors 1505 (1505a, 1505b, and 1505c to the BSE image 309B corresponding to the image type used for the measurement of the lower layer pattern. Note that, the functions described in the embodiment perform processing of generating the region divided image 311, the measurement area cursor, and the like based on the same measurement target image 309, which is an input source image. Therefore, when the measurement area cursor disposed image 313 is to be generated by disposing a measurement area cursor generation result 1509 as shown in FIG. 15 in the measurement target image 309, no unnecessary deviation is generated.

Note that, as in the lower right set shown as an example, when the measurement area cursor is not generated and disposed based on the measurement area cursor possibility determination rule, the measurement system 100 may output, to the user U1 on the screen, information indicating that the measurement area cursor is not generated and disposed based on the measurement area cursor possibility determination rule regarding the corresponding location.

### [Edge Detection in Measurement Area Cursor and Calculation of Center of Gravity Coordinates]

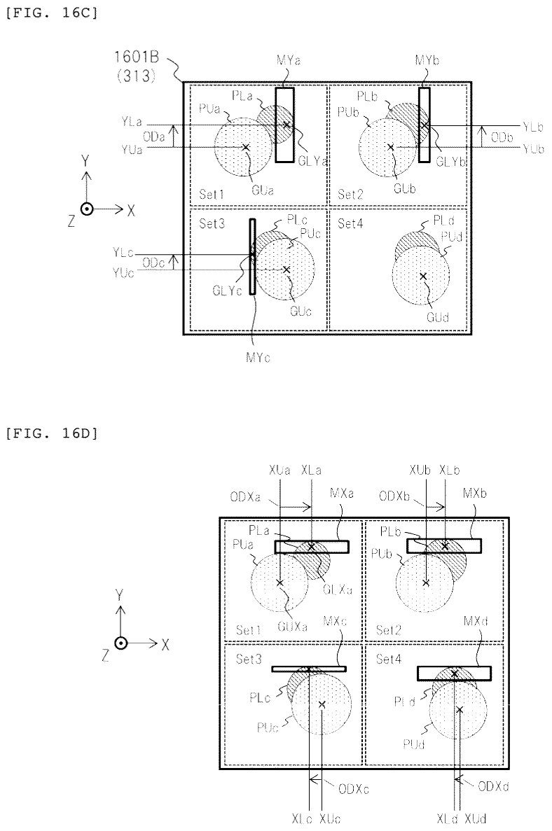

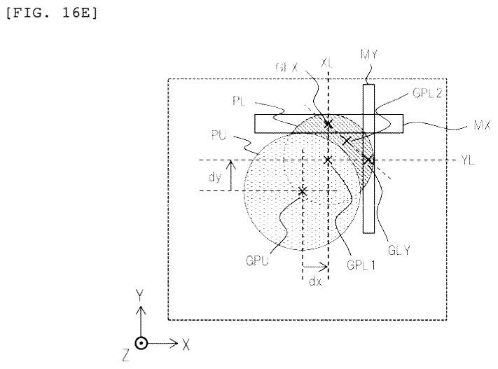

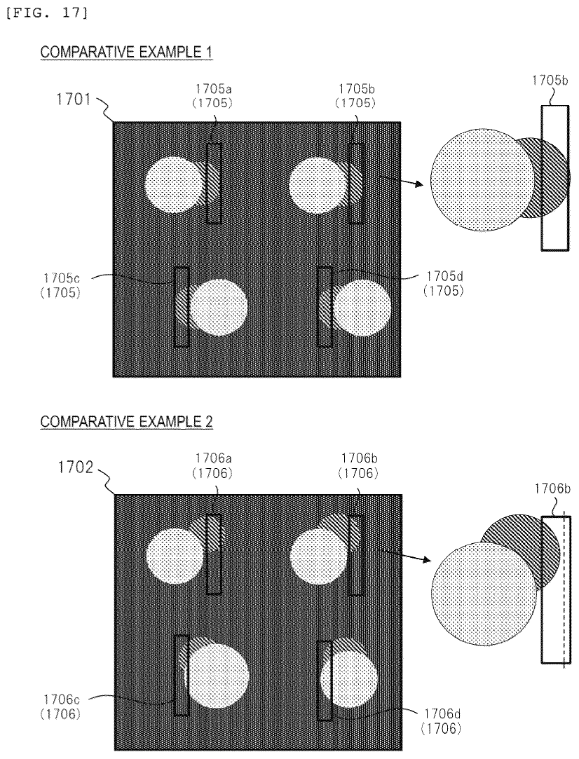

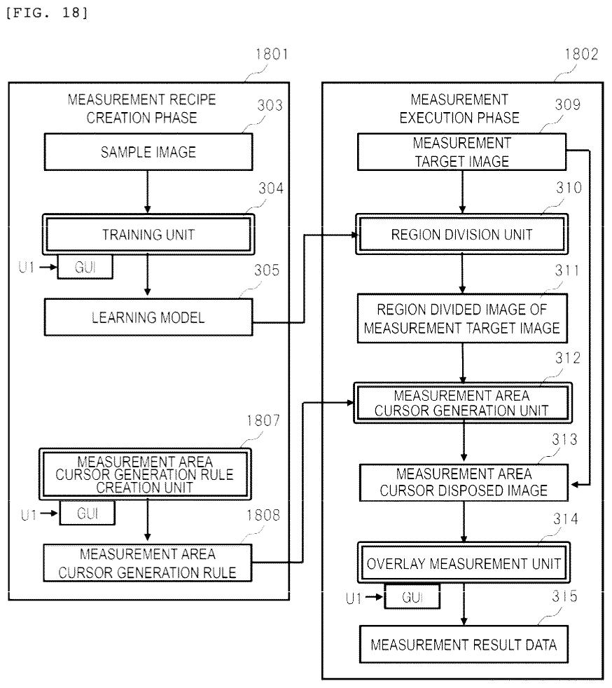

FIG. 16A is a diagram illustrating a specific example of the edge detection in the measurement area cursor in step S1406 and the calculation of the center of gravity coordinates in step S1407 after the measurement area cursor is disposed, as the generation process in the flow in FIG. 14. FIG. 16B is a table showing an example of a processing result of the calculation of the overlay deviation amount in step S1408.

In FIG. 16A, an image 1601B on the left side corresponds to the measurement area cursor disposed image 313 which is an image obtained by disposing the measurement area cursor in the BSE image 309B in FIG. 15. An image 1601A on the right side is the measurement area cursor disposed image 313 which is an image obtained by disposing the measurement area cursor in the SE image 309A. In the measurement area cursor disposed image 1601A, the measurement area cursor is disposed with respect to the upper layer pattern, and in the measurement area cursor disposed image 1601B, the measurement area cursor is disposed with respect to the lower layer pattern. The measurement area cursor disposed image 1601A includes measurement area cursors 1605a, 1605b, 1605c, and 1605d as a measurement area cursor 1605.

For the disposition of the measurement area cursor with respect to the upper layer pattern, the method shown in FIG. 15 using the lower layer pattern as an example may be similarly used. Alternatively, when the disposition of the measurement area cursor with respect to the upper layer pattern does not influence the measurement accuracy of the overlay deviation amount by the disposition of the measurement area cursor, a method in the related art may be used. In the lower layer pattern as an example, since the measurement accuracy of the overlay deviation amount is influenced by the disposition of the measurement area cursor, the method shown in FIG. 15 in the present embodiment is used instead of the method in the related art.

An edge detection result 1602B indicates an example of a result of detecting edges of the lower layer pattern from a profile in the measurement area cursor 1505 for the lower layer pattern in the measurement area cursor disposed image 1601B. An edge detection result 1602A indicates an example of a result of detecting edges of the upper layer pattern from a profile in the measurement area cursor 1605 for the upper layer pattern in the measurement area cursor disposed image 1601A. These results correspond to the results of the edge detection in step S1406. Since the measurement area cursor in this example is for measurement in the Y direction, the profile here is a brightness profile in the Y direction. Edges a1 and a2 are edge positions of a certain lower layer pattern in the Y direction. Edges b1 and b2 are edge positions of a certain upper layer pattern in the Y direction.

For example, in the measurement area cursor 1505a of a region element in a certain lower layer pattern 1611, a profile at a certain X position (indicated by a dashed straight line) is referred to. The profile at the X position includes upper and lower edges of the lower layer pattern between the profile and the background region in the Y direction. The X position may be a center of a width of the measurement area cursor 1505a in the X direction. Alternatively, in the measurement area cursor 1505a, the edge position may be calculated by statistics based on the profile of each X position. The same applies to the measurement area cursor 1605a of a region element in a certain upper layer pattern 1612.

A center of gravity coordinate display image 1603B is an example of a result of the center of gravity Y coordinate of the lower layer pattern, which is calculated based on the edge detection result 1602B of the lower layer pattern. A center of gravity coordinate display image 1603A is an example of a result of the center of gravity Y coordinate of the upper layer pattern, which is calculated based on the edge detection result 1602A of the upper layer pattern. These results correspond to the results of the calculation of the center of gravity coordinates in step S1407. A center of gravity position including the center of gravity Y coordinate and a representative X coordinate of each X coordinate used for the measurement, in other words, an X coordinate of the center, is shown by an x mark. For example, the center of gravity Y coordinate (referred to as BY1) of a region element corresponding to a certain lower layer pattern is obtained as BY1=(Ya1+Ya2)/2 from a Y coordinate Ya1 of the edge a1 and a Y coordinate Ya2 of the edge a2. Similarly, the center of gravity Y coordinate (referred to as BY2) of a region element corresponding to a certain upper layer pattern is obtained as BY2=(Yb1+Yb2)/2 from a Y coordinate Yb1 of the edge b1 and a Y coordinate Yb2 of the edge b2.

As shown in the center of gravity coordinate display image 1603B, the coordinates (the center of gravity Y coordinate BY1 and a center of gravity X coordinate BX1) of the center of gravity (x mark) of a certain lower layer pattern are obtained. Similarly, the center of gravity (x mark) of another lower layer pattern is obtained for each measurement area cursor. Similarly, as shown in the center of gravity coordinate display image 1603A, the coordinates (the center of gravity Y coordinate BY2 and a center of gravity X coordinate BX2) of the center of gravity (x mark) of a certain upper layer pattern are obtained. Similarly, the center of gravity (x mark) of another upper layer pattern is obtained for each measurement area cursor.

### [Overlay Measurement Result]

A table 1600 in FIG. 16B is an example of overlay measurement result data, and shows data of the center Y coordinate (referred to as YL) of the lower layer pattern and the center Y coordinate (referred to as YU) of the upper layer pattern for each set of adjacent patterns, and an overlay deviation amount calculated value (referred to as OD) calculated based on each of YL and YU according to the following Equation 1. This corresponds to the result in step S1408. Here, a case where the center of gravity coordinates in FIG. 16A described above are used as the center coordinates is shown.

$$OD = YL - YU \qquad Equation 1$$

A set of adjacent patterns is a pattern pair of an upper layer pattern and lower layer pattern overlapping each other, corresponds to a measurement target pattern for each rule target region in, for example, FIG. 11A, and is subjected to data management with an ID. In this example, the ID of the set is Set1 to Set4. For example, for the Set1, the center Y coordinate of the lower layer pattern is a Y coordinate 1 (YLa), the center Y coordinate of the upper layer pattern is a Y coordinate 2 (YUa), and the overlay deviation amount calculated value ODa=YLa−YUa. The above BY1 can be used for the Y coordinate 1 (YLa), and the above BY2 can be used for the Y coordinate 2 (YUa). For the Set4, since the center Y coordinate of the lower layer pattern is not measured based on no disposition of the measurement area cursor, the OD is also not measured.

In addition, the overlay deviation amount of the entire measurement target image may be calculated and output based on the overlay deviation amount calculated value (OD) of each set by a method of calculating a statistic by, for example, an arithmetic mean. Instead of the arithmetic mean, a geometric mean, a median, or a fluctuation amount such as a standard deviation may be calculated and output.

### [Overlay Deviation Amount]

FIG. 16C is a schematic enlarged view of the measurement area cursor disposed image 1601B (313), which is an image obtained by disposing the measurement area cursor in the BSE image including the lower layer pattern, as a diagram illustrating the overlay deviation amount. Here, the background region is shown in white. In addition, center of gravity positions (GLYa, GLYb, GLYc) including center of gravity Y coordinates (YLa, YLb, YLc) of the measurement area cursors 1505 in respective lower layer patterns are shown in an overlapping manner with x marks. In addition, center of gravity positions (GUa, GUb, GUc, GUd) including center of gravity Y coordinates (YUa, YUb, YUc, YUd) on respective upper layer pattern sides are shown in an overlapping manner with x marks.

For a certain set Set1, a measurement area cursor MYa for a lower layer pattern PLa is set by taking a correction value with respect to the reference position as in FIG. 22. The measurement area cursor MYa includes the lower layer pattern PLa at each position in the X direction, and does not include any portion consisting only of the background region. The measurement area cursor MYa does not include a boundary with the upper layer pattern. Therefore, the edges and the center of gravity Y coordinate of the lower layer pattern can be suitably calculated based on the measurement area cursor MYa as described above (FIG. 16A). In this manner, by setting a suitable measurement area cursor so as to exclude an unnecessary region in which the accuracy can be reduced, the center of gravity Y coordinate can be calculated with high accuracy.

For the upper layer pattern and the lower layer pattern of the Set1, the overlay deviation amount calculated value (ODa) in the Y direction is ODa=(YLa−YUa). Similarly, for the Set2, an overlay deviation amount calculated value (ODb) in the Y direction is ODb=(YLb−YUb). For the Set3, an overlay deviation amount calculated value (ODc) in the Y direction is ODc=(YLc−YUc). The overlay deviation amount can be represented by, for example, a pixel distance in an image or a coordinate difference value.

Further, when the overlay deviation amount in the entire measurement target image is to be calculated based on the overlay deviation amount calculated values (ODa, ODb, ODc) of respective sets by, for example, an arithmetic mean, the overlay deviation amount is obtained as (ODa+ODb+ODc)/3.

FIG. 16D shows an example of an image obtained by disposing a measurement area cursor in a case of calculating the center of gravity of the lower layer pattern in the X direction when the overlay deviation amount in the X direction is to be measured. Separately, the measurement area cursor generation rule 308 suitable for calculating the center of gravity in the X direction is set, and a measurement area cursor is generated based on the rule as shown, for example. For example, for the Set1, a measurement area cursor MXa is disposed in the lower layer pattern PLa. A center of gravity GLXa (including a center of gravity X coordinate XLa) of the lower layer pattern PLa is calculated based on the measurement area cursor MXa. Similarly, a center of gravity GUXa (including a center of gravity X coordinate XUa) of an upper layer pattern PUa is calculated. An overlay deviation amount calculated value ODXa between the lower layer pattern PLa and the upper layer pattern PUa in the X direction is ODXa=(XLa−XUa).

As in the above example, for the same measurement target pattern, measurement area cursors based on the measurement area cursor generation rule 308 are set in the X direction and the Y direction, and different center of gravity coordinates (for example, the center of gravity GLYa and the center of gravity GLXa) are calculated. The center of gravity coordinates obtained based on these measurement area cursors are generated and calculated such that the overlay deviation amount can be calculated with high accuracy.

### [Modification: Center of Gravity Calculation]

As a modification, as described above, for a certain measurement target pattern, the center of gravity X coordinate calculated based on the measurement area cursor generation rule in the X direction and the center of gravity Y coordinate calculated based on the measurement area cursor generation rule in the Y direction may be used and integrated to calculate the center of gravity of the measurement target pattern.

FIG. 16E is a diagram illustrating the calculation of the center of gravity in the modification. A target image includes a lower layer pattern PL and an upper layer pattern PU as a certain set. In this example, a degree of overlapping of the upper layer pattern PU with the lower layer pattern PL is large, and most of the lower layer pattern PL is shielded. A boundary of the lower layer pattern PL that is hidden and invisible is indicated by a dashed circle, and a center of the dashed circle is indicated by a center point. For the upper layer pattern PU, a center of gravity GPU is obtained. For the lower layer pattern PL, a measurement area cursor MY is set based on the measurement area cursor generation rule in the Y direction. A center of gravity Y coordinate GLY is calculated based on the measurement area cursor MY. In addition, for the lower layer pattern PL, a measurement area cursor MX is set based on the measurement area cursor generation rule in the X direction. A center of gravity X coordinate GLX is calculated based on the measurement area cursor MX. The overlay deviation amount can be calculated based on each of the two types of center of gravity coordinates (GLX, GLY) by the method described above.

Here, in the modification, the center of gravity of the lower layer pattern PL is calculated by integrating the two types of center of gravity coordinates (GLX, GLY). As one method, as shown in the drawing, the center of gravity X coordinate GLX and the center of gravity Y coordinate GLY may be used as position coordinates (GLX, GLY) of a new center of gravity GPL1. As another method, the center of gravity X coordinate GLX and the center of gravity Y coordinate GLY may be connected by a straight line, and an intermediate point of the straight line may be set as a new center of gravity GPL2. Thereafter, the overlay deviation amount only needs to be calculated using the center of gravity GPL1 or the center of gravity GPL2 of the lower layer pattern PL and the center of gravity GPU of the upper layer pattern PU. For example, in a case of using the center of gravity GPL1, deviation amounts dx and dy in the respective directions are obtained as indicated by arrows in the drawing.

### Effects of Embodiment 1

As described above, according to Embodiment 1, regarding the measurement of the overlay deviation amount or the like, even when the boundary of the pattern is unclear or when the process variation amount is large and the variation in size or position of the pattern in the measurement target image is large, the overlay deviation amount of the like can be measured stably, in other words, with higher accuracy. According to Embodiment 1, by generating the region divided image of the measurement target image, it is possible to acquire a positional relationship between measurement target patterns apart from each other in the measurement target image, for example, a set of an individual upper layer pattern and an individual lower layer pattern adjacent to each other. According to Embodiment 1, by applying the predetermined measurement area cursor generation rule to the region divided image, a suitable measurement area cursor can be generated and disposed in the measurement target image according to the influence of the process variation on the pattern. According to Embodiment 1, the overlay deviation amount or the like of the measurement target pattern can be calculated with high accuracy using the measurement area cursor.

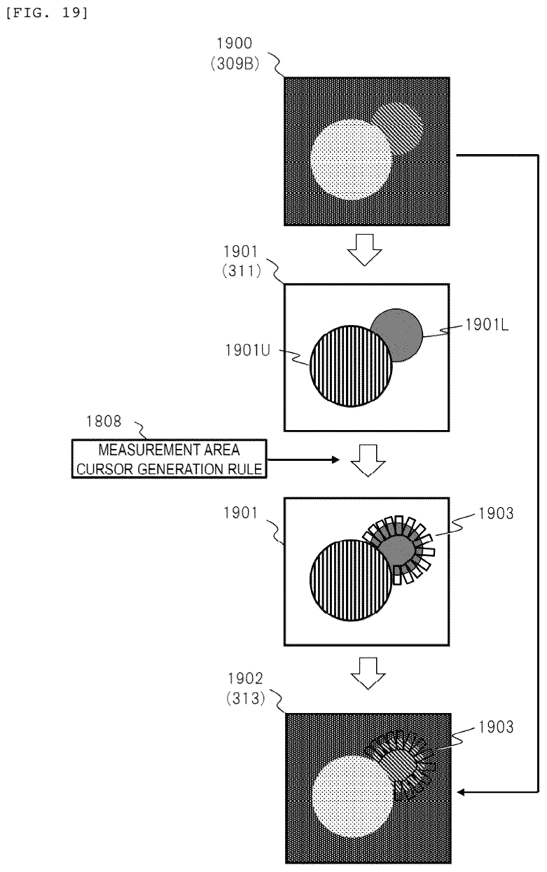

In the technique as disclosed in PTL 2, a standard measurement area cursor is set for a standard measurement target image. FIG. 17 is a diagram illustrating comparative examples. An image 1701 in Comparative Example 1 in FIG. 17 is an example in which standard measurement area cursors 1705 (1705a, 1705b, 1705c, and 1705d) are set for a standard measurement target image. The measurement area cursor 1705b in the upper right set is schematically shown in an enlarged manner.

Therefore, in the technique as disclosed in PTL 2, when the setting of the measurement area cursor is applied to the measurement target image obtained by capturing the structure in which the size or the position of the pattern is largely changed as shown in FIG. 6, the measurement area cursor cannot appropriately capture only the lower layer pattern. An image 1702 in Comparative Example 2 in FIG. 17 is a case where setting of a standard measurement area cursor is applied to a measurement target image having a fluctuation in position and size as in FIG. 6, similar to Comparative Example 1. The image 1702 has measurement area cursors 1706 (1706a, 1706b, 1706c, and 1706d, and a position and a shape of the measurement area cursor 1706 are the same as those of the measurement area cursor 1705 (1705a, 1705b, 1705c, and 1705d). The measurement area cursor 1706b in the upper right set is schematically shown in an enlarged manner.

In the image 1702, for example, the measurement area cursor 1706b includes a background portion without a lower layer pattern in the X direction (for example, a position of a dashed straight line). In the measurement area cursor 1706b, edges of the background portion without a lower layer pattern are detected, and suitable edge detection cannot be performed. The measurement area cursor 1706c is set to include a background portion and an upper layer pattern, an edge between the background portion and the upper layer pattern is detected, and suitable edge detection cannot be performed. In addition, since the measurement area cursor 1706d has no portion including only the lower layer pattern in the X direction, suitable edge detection cannot be performed.

Therefore, in the measurement area cursor 1706b or the like, erroneous center of gravity coordinates, in other words, low accuracy center of gravity coordinates are calculated based on an erroneous edge detection result of the lower layer pattern. In the measurement based on the center of gravity coordinates, an erroneous overlay deviation amount, in other words, a low accuracy overlay deviation amount is calculated and output.

In addition, in the image 1702, since the number of the measurement area cursors is fixed, for example, the measurement area cursor 1706d is disposed even when the edge detection necessary for calculating the center of gravity coordinates of the lower layer pattern cannot be performed. Accordingly, in the measurement area cursor 1706d, the edge detection cannot be performed, and the center of gravity coordinates of the lower layer pattern cannot be calculated. Alternatively, in the measurement area cursor 1706d, there is a possibility that the edge detection for the upper layer pattern is erroneously performed.

On the other hand, according to Embodiment 1, as shown in FIG. 15 and the like, even when the fluctuation or variation amount of the size or the position of the pattern in the measurement target image is large, a suitable measurement area cursor for capturing the measurement target pattern can be disposed based on the measurement area cursor generation rule 308. In addition, in Embodiment 1, by also using the measurement area cursor possibility determination rule, it is possible not to dispose the measurement area cursor when the edge detection necessary for the calculation of the center of gravity coordinates cannot be performed. Therefore, according to Embodiment 1, it is possible to improve the accuracy of measurement of the overlay deviation amount or the like by using a suitable measurement area cursor.

In addition, in the technique as disclosed in PTL 1, even for a measurement target image having an unclear edge, the pattern is binarized based on an inference result, and the center of gravity coordinates are calculated based on the binarized image. Therefore, in the technique as disclosed in PTL 1, there is a possibility that the correct center of gravity coordinates cannot be calculated unless all the boundaries between the upper layer pattern and the lower layer pattern are correctly inferred.

On the other hand, in Embodiment 1, the user U1 can set the measurement area cursor generation rule 308 based on comparison between the sample image 303 and the region divided image 306 of the sample image 303 (FIG. 13A and the like). Therefore, a region having an unclear boundary, for example, a boundary portion between the upper layer pattern and the lower layer pattern or a boundary portion between the lower layer pattern and the background can be excluded from being provided with a measurement area cursor, and a suitable measurement area cursor can be disposed only in a region where the lower layer pattern is present (for example, FIG. 22 or 26). In addition, the edge of the measurement target pattern can be automatically measured based on a profile of continuous shading in the measurement area cursor of the measurement target image 309 (FIG. 16A). Accordingly, according to Embodiment 1, even when the boundary of the pattern is unclear, it is possible to improve the accuracy of measurement of the overlay deviation amount or the like by using a suitable measurement area cursor, unlike in the technique as disclosed in PTL 1.

Further, when the lower layer pattern is always shielded by the upper layer pattern, or when most of the lower layer pattern is shielded by the upper layer pattern, it is generally difficult to accurately calculate, based on a binary image of an unshielded region of the lower layer pattern, the center of gravity coordinates of the lower layer pattern including a shielded region. In contrast, in Embodiment 1, for example, by disposing a suitable measurement area cursor based on the measurement area cursor generation rule 308 for calculating the center of gravity coordinate in the Y direction with high accuracy, it is possible to calculate the center of gravity coordinates in the Y direction of the lower layer pattern including the shielded region with high accuracy even in such a case.

With the progress of miniaturization of semiconductor devices, the influence of the process variation on the pattern size or the like has become relatively large, and the boundary between upper and lower layer patterns or the like of a three-dimensional structure has become unclear. In a method of disposing a standard measurement area cursor in the related art, it is not possible to follow an actual pattern variation. In this method, a width and the number of measurement area cursors, a positional relationship between the measurement area cursors, and the like are fixed. In contrast, according to Embodiment 1, by using the measurement area cursor generation rule, it is possible to optimize the measurement area cursor, which is a measurement range, according to a situation such as the actual position or size of the region element corresponding to the pattern structure of the measurement target image, and to dispose a suitable measurement area cursor for each individual pattern structure. Accordingly, it is easier to detect and measure the edge, the center of gravity, and the like of the pattern, and the measurement accuracy of the overlay deviation amount or the like can be improved.

In addition, the edge of the region element in the region divided image may not match the edge of the actual pattern structure due to unclearness or the like (for example, FIG. 26), a degree of deviation thereof has a certain tendency. In contrast, in Embodiment 1, by using the correction value, the measurement area cursor generation rule is applied such that the measurement area cursor is reliably disposed in a region estimated to be the measurement target pattern, in other words, an uncertain region is excluded. In Embodiment 1, the measurement area cursor generation rule is applied to the region element of the region divided image so as to determine a correction relationship between the contour of the pattern structure and the measurement area cursor. Accordingly, the measurement accuracy can be improved.

### [Dimension Measurement]

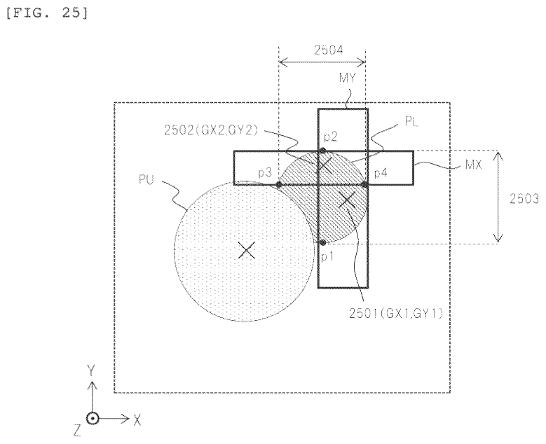

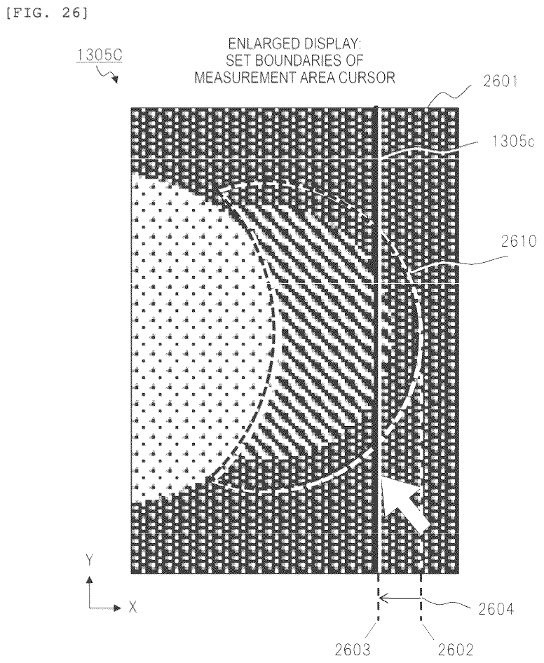

FIG. 25 shows an example of measurement of a dimension or the like of the lower layer pattern as an example of measurement of parameter values other than the overlay deviation amount. For a certain set, a width in the X direction and a width in the Y direction are measured as the dimension of the lower layer pattern PL. A center of gravity 2501 (center of gravity X coordinate GX1, center of gravity Y coordinate GY1) is obtained based on the measurement area cursor MY for the Y direction, and a center of gravity 2502 (center of gravity X coordinate GX2, center of gravity Y coordinate GY2) is obtained based on the measurement area cursor MX for the X direction.

Regarding a shape of the lower layer pattern PL, since the edge can be detected based on each measurement area cursor as described above, the shape (for example, an arc) of the boundary with the background region can be measured.

By using edges that can be detected based on the measurement area cursor MY, for example, maximum and minimum edge points p1 and p2, it is possible to calculate a width 2503 in the Y direction for a portion of the lower layer pattern PL that is visible without being shielded. Similarly, by using edges that can be detected based on the measurement area cursor MX, for example, maximum and minimum edge points p3 and p4, a width 2504 in the X direction for a portion of the lower layer pattern PL that is visible without being shielded can be calculated.

The width 2504 in the X direction and the width 2503 in the Y direction are schematic widths of the portions of the lower layer pattern PL that are visible without being shielded.

Center point coordinates of the lower layer pattern PL can be measured by, for example, the method shown in FIG. 16E described above. Alternatively, the center point coordinates may be calculated using the shape and the width measured above.

As in the above example, by using the measurement area cursor generation rule 308 and the measurement area cursor, the dimension of the pattern or the like can also be measured.

### Modifications of Embodiment 1

In Embodiment 1, the case using unsupervised learning has been described as described above, but the components may be changed as follows.

As a modification, supervised learning may be applied. For example, the training unit 304 in FIG. 3 may train the learning model 305 using not only the sample image 303 but also training data in which the user U1 annotates the region element with respect to the sample image 303. Accordingly, a correspondence relationship between the region type and the pattern type at the time of generating the region divided image 306 is clear, so that the measurement area cursor generation rule 308 can be easily set.

As a modification, a rule-based method may be applied to the generation of the region divided image 306 instead of the machine learning. The computer generates the region divided image 306 from the sample image 303 by rule-based processing without generating the learning model 305 in FIG. 3. The user U1 sets a generation rule (region divided image generation rule) on the screen. During the measurement, the region division unit 310 generates the region divided image 311 from the measurement target image 309 using the rule. In this modification, effects similar to those in Embodiment 1 can also be obtained.

### Embodiment 2

Embodiment 2 will be described. A basic configuration in Embodiment 2 is the same as the configuration in Embodiment 1, and in the following, components in Embodiment 2 different from those in Embodiment 1 will be mainly described. The main difference in Embodiment 2 is the functional block configuration in FIG. 3.

In Embodiment 1, the method in which the user U1 checks the region divided image on the screen (FIG. 13A and the like) and creates and sets the measurement area cursor generation rule 308 has been described. In Embodiment 2, there will be described a method in which a measurement system generates a measurement area cursor by acquiring a measurement area cursor generation rule from a storage unit (not shown) without requiring a procedure in which the user U1 checks a region divided image on a screen. In Embodiment 2, the measurement area cursor generation rule is designed and prepared as a rule-based program in advance.

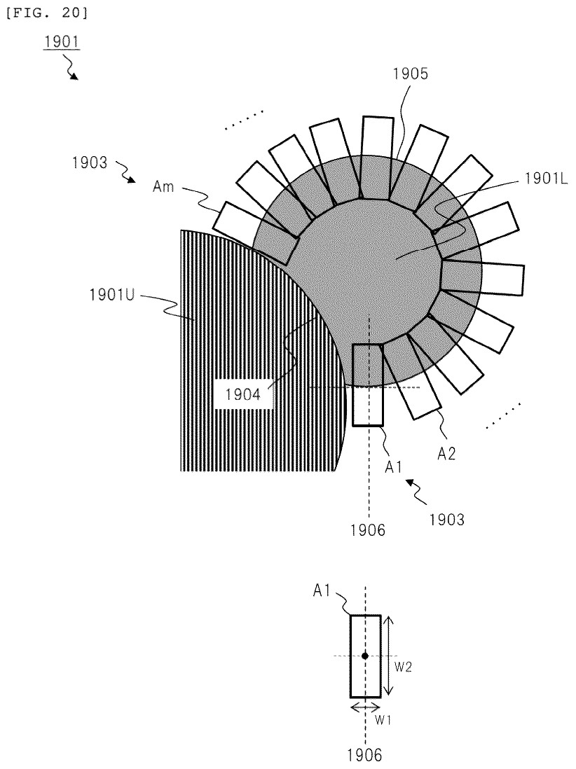

FIG. 18 shows a functional block configuration according to Embodiment 2. FIG. 18 is different from FIG. 3 in a measurement area cursor generation rule creation unit 1807 and a measurement area cursor generation rule 1808. In FIG. 18, there is no region divided image 306 described above. In this configuration, separately from the generation of the learning model 305, the measurement area cursor generation rule 1808, which does not depend on a measurement target such as an overlay deviation amount, is created and set in advance without the user U1 checking the region divided image.

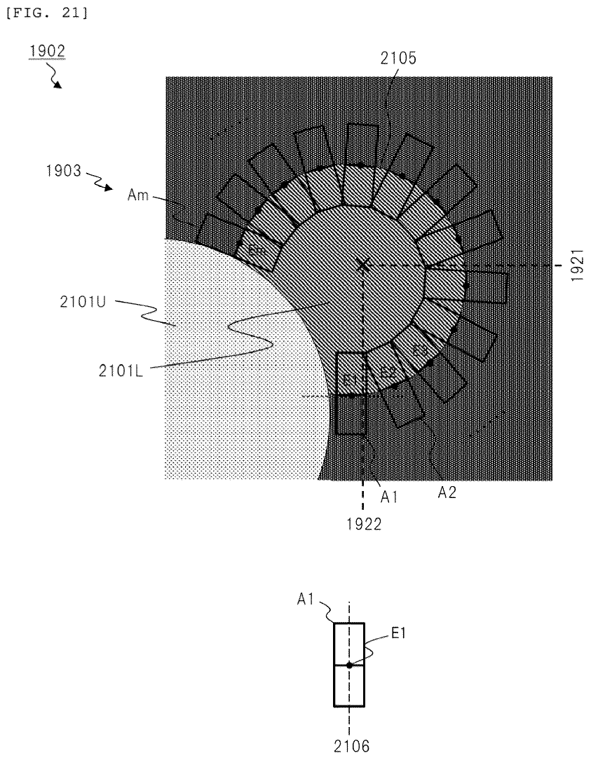

The measurement area cursor generation rule 1808 here includes the following rules in the case of generating a measurement area cursor for lower layer pattern measurement, for example. The rule is, for example, a rule for identifying a region type corresponding to an upper layer pattern and a region type corresponding to a lower layer pattern and disposing a plurality of measurement area cursors in a direction of a boundary of a region element corresponding to the lower layer pattern (FIG. 19). Here, as a method of identifying the region type corresponding to the upper layer pattern and the region type corresponding to the lower layer pattern, for example, there is a method of identifying the region type by acquiring brightness information of an SE image or a BSE image at a position of the region element of each region type and comparing the brightness information. This identification step can be skipped when the region divided image has been obtained using supervised learning or rule-based techniques, which is a modification of Embodiment 1. The measurement area cursor generation rule 1808 includes, for example, a rule that does not include the region element corresponding to the upper layer pattern in the measurement area cursor. In the measurement area cursor generation rule 1808, a width, a height, and the like of each of the plurality of measurement area cursors are set.

FIG. 19 shows an example of generation from the measurement target image 309 to the measurement area cursor disposed image 313. A measurement target image 1900 indicates, for example, a portion, i.e., one set in the BSE image 309B. From the measurement target image 1900, a region divided image 1901 is generated as an example of the region divided image 311. For the region divided image 1901, a measurement area cursor 1903 is generated based on the measurement area cursor generation rule 1808. Then, the measurement area cursor 1903 is disposed in the measurement target image 1900, and a measurement area cursor disposed image 1902 is obtained as an example of the measurement area cursor disposed image 313. The region divided image 1901 includes a region element 1901U of an upper layer pattern (first region type) and a region element 1901L of a lower layer pattern (second region type) in a certain set. This example shows a case where the measurement area cursor 1903 for the lower layer pattern measurement is generated.

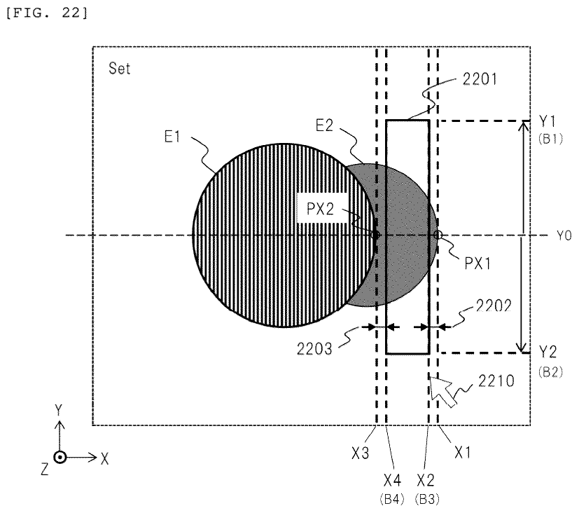

FIG. 20 shows, as a partially enlarged view of the region divided image 1901 in FIG. 19, a state where a plurality of measurement t area cursors 1903 are generated based on the measurement area cursor generation rule 1808 for the region element 1901L corresponding to the lower layer pattern. The measurement area cursor generation rule 1808 is a rule for generating a necessary number (m) of measurement area cursors 1903 {A1, A2, . . . , Am} along a boundary 1905 (for example, an arc) with a background, which does not include a boundary 1904 with the upper layer pattern 1901U, in the region element 1901L corresponding to the lower layer pattern in the region divided image 1901. In addition, the measurement area cursor generation rule 1808 is a rule for disposing, for example, a rectangular measurement area cursor 1903 extending in a normal direction 1906 with respect to a tangent of the boundary 1905 for each measurement area cursor 1903. A processor of a computer executes processing based on a program of the measurement area cursor generation rule 1808.

In this example, a width W1 in a tangential direction, a height W2 (width in a longitudinal direction) in the normal direction 1906, and the like of the rectangle of each measurement area cursor 1903 can be set and are set in advance. In addition, the number, pitch, or the like of the measurement area cursors 1903 to be disposed in the direction along the boundary 1905 can be set.

In this example, a plurality of measurement area cursors 1803 are disposed at an interval along the boundary 1905, and there are a portion covering the boundary 1905 and a portion not covering the boundary 1905, but the disclosure is not limited thereto, and the plurality of measurement area cursors 1803 may be disposed so as to cover the entire boundary 1905 along the boundary 1905. For example, in another measurement area cursor generation rule, a ring-shaped region partially missing may be generated as one measurement area cursor in accordance with the arc of the boundary 1905 of the region element 1901L corresponding to the lower layer pattern.

In a measurement execution phase 1802 in FIG. 18, when the measurement is executed, the measurement area cursor generation unit 312 generates the measurement area cursor 1903 according to the measurement area cursor generation rule 1808 based on the region divided image 311 (1901) automatically generated from the measurement target image 309 (1900), and obtains the measurement area cursor disposed image 313 (1902). Then, the overlay measurement unit 314 measures the overlay deviation amount or the like based on the measurement area cursor disposed image 313 (1902) using the measurement area cursor 1903.

FIG. 21 shows the measurement area cursor disposed image 1902 corresponding to the example in FIG. 20, and shows an example of edge calculation and center of gravity calculation for a lower layer pattern 2101L using a measurement area cursor 103. In this example, during the measurement, the overlay measurement unit 314 can detect an edge corresponding to a boundary 2105 of a lower layer pattern 2101L (a portion in the rectangle of the measurement area cursor 1903) based on brightness profile of a portion in each measurement area cursor 1903 in the lower layer pattern 2101L. For example, in a measurement area cursor A1, an edge point E1 can be detected based on a profile at a position such as a line 2106 along the normal direction 1906. That is, in this example, a plurality of edge portions (edge points E1, E2, . . . , Em) can be detected corresponding to the plurality of (m) measurement area cursors 1903 (A1 to Am).

After the edge detection, the overlay measurement unit 314 calculates, for example, a center of gravity Y coordinate of the lower layer pattern 1901L based on the plurality of edge portions. For example, the overlay measurement unit 314 calculates a center of gravity Y coordinate 1921 based on coordinates of the plurality of (m) edge points {E1, E2, . . . , Em} by, for example, statistics. The overlay measurement unit 314 may calculate a center of gravity X coordinate 1922 based on the coordinates of the plurality of (m) edge points. On the other hand, the overlay measurement unit 314 calculates, for example, a center of gravity Y coordinate and a center of gravity X coordinate of the upper layer pattern 1901U by using the same method as that of the lower layer pattern or a method in the related art.

Then, the overlay measurement unit 314 can calculate an overlay deviation amount in a Y direction based on a difference between the center of gravity Y coordinate of the lower layer pattern 1901L and the center of gravity Y coordinate of the upper layer pattern 1901U, and can similarly calculate an overlay deviation amount in an X direction.

The edge detection will be supplementarily described. An edge (boundary) of the region element 1901L corresponding to the lower layer pattern in the region divided image 1901 may not match the edge of the lower layer pattern 2101L in the measurement target image 1900. However, there is an edge of the lower layer pattern 2101L near the edge of the region element 1901L with a certain tendency and sense of distance. Therefore, in the measurement area cursor generation rule 1808, the measurement area cursor 1903 having a size in the normal direction 1906 of the edge (boundary 1905) of the region element 1901L corresponding to the lower layer pattern is disposed in the region divided image 1901. Then, the edge of the lower layer pattern 2101L of the measurement target image 1900 enters the measurement area cursor 1903 with a high probability. Therefore, the edge of the lower layer pattern 2101 can be detected with high accuracy in the measurement area cursor 1903, and the center of gravity can be calculated with high accuracy based on the edge.

### Effects of Embodiment 2

As described above, according to Embodiment 2, since the user U1 can set the common measurement area cursor generation rule 1808 for measurement target patterns having an overlay deviation amount t and having different pattern shapes or dispositions without the need for the user U1 to view and check the region divided image, it is possible to obtain effects similar to those in Embodiment 1 while reducing a setting work amount. Once the program of the measurement area cursor generation rule designed based on the rule is created and set, the user U1 can then easily do the work of setting the measurement area cursor generation rule since it is only necessary to select and apply the rule. In addition, programs of a plurality of types of measurement area cursor generation rules may be prepared.

Embodiments of the disclosure have been specifically described above, but the disclosure is not limited to the above embodiments, and various modifications can be made without departing from the scope of the disclosure. In each embodiment, components can be added, deleted, replaced, or the like except for essential components. Unless otherwise specified, each component may be single or plural. The embodiments and the modifications can be combined.

As described in each embodiment and modification, there may be a plurality of types of measurement area cursor generation rules. A form in which a plurality of types of measurement area cursor generation rules are combined is also possible, and it is possible to select and apply the measurement area cursor generation rule from these rules.

The technique in the disclosure has an effect of improving accuracy of measurement for a semiconductor device. Therefore, the technique in the disclosure contributes to achieving high levels of economic productivity through technological improvement and innovation in order to achieve the Sustainable Development Goals (SDGs), particularly “Decent work and economic growth” in Goal 8.

The technique in the disclosure is not limited to the above embodiments, and includes various modifications. For example, in the components of the measurement system 100, the input/output device 105 may be a touch panel. The processor such as the main processor 104 may include an MPU, a CPU, a GPU, an FPGA, a quantum processor, or other semiconductor devices capable of performing arithmetic operations. The computer constituting the measurement system 100 may be, for example, a personal computer (PC), a tablet terminal, a smartphone, a server computer, a blade server, a cloud server, or an aggregate of computers. The controller 102, the main computer 104, the first sub-computer 107, and the second sub-computer 109 may share some or all of hardware. In addition, the program related to the overlay measurement may be stored in a computer-readable non-volatile memory medium or the like. In this case, the program may be read from an external recording medium input/output device (not shown) and the program may be executed by the processor.

### APPENDIX

The followings are also possible as embodiments. A measurement system according to an embodiment is a measurement system for a semiconductor device, and includes: a microscope; and a processor, in which the processor acquires an image of a structure of the semiconductor device captured by the microscope, acquires a measurement area cursor generation rule related to the structure, generates a measurement area cursor to be disposed with respect to the structure based on the image and the measurement area cursor generation rule, disposes the measurement area cursor with respect to the structure in the image, and performs measurement related to the structure using a portion of the image in the measurement area cursor.

A program according to an embodiment is a program for causing a computer including a processor to execute processing, and the processing to be executed by the processor includes processing of acquiring an image of a structure of a semiconductor device captured by a microscope, processing of acquiring a measurement area cursor generation rule related to the structure, processing of generating a measurement area cursor to be disposed with respect to the structure based on the image and the measurement area cursor generation rule, processing of disposing the measurement area cursor with respect to the structure in the image, and processing of performing measurement related to the structure using a portion of the image in the measurement area cursor.

A storage medium according to an embodiment is a non-transitory computer-readable storage medium storing the program, for example, a memory card or a disk.

In the measurement system according to the embodiment, the processor sets a rule target region, which is a region including a structure to which the measurement area cursor generation rule is to be applied, in a region divided image based on an operation of checking the region divided image by a user on a screen, and generates the measurement area cursor by applying the measurement area cursor generation rule for each rule target region.

In addition, as the structure, the processor disposes the measurement area cursor in an SE image in a case of measuring an upper layer pattern, and disposes the measurement area cursor in a BSE image in a case of measuring a lower layer pattern.

In addition, the processor detects an edge of the structure based on a portion in the measurement area cursor, calculates a center of gravity of the structure based on the edge, and performs measurement based on the center of gravity.

### REFERENCE SIGNS LIST

100 measurement system
101 SEM
101A main body
102 controller
104 main computer
105 input/output device
107 first sub-computer
109 second sub-computer
201 sample
303 sample image
304 training unit
305 learning model
306 region divided image
307 measurement area cursor generation rule creation unit
308 measurement area cursor generation rule
309 measurement target image
310 region division unit
311 region divided image
312 measurement area cursor generation unit
313 measurement area cursor disposed image
314 overlay measurement unit
315 measurement result data

1. A measurement system for a semiconductor device, the measurement system comprising:
a microscope; and
a processor, wherein
the processor
acquires an image of a structure of the semiconductor device captured by the microscope,
acquires a measurement area cursor generation rule related to the structure,
generates a measurement area cursor to be disposed with respect to the structure based on the image and the measurement area cursor generation rule,
disposes the measurement area cursor with respect to the structure in the image, and
performs measurement related to the structure using a portion of the image in the measurement area cursor.

2. The measurement system according to claim 1, wherein
the processor
generates a region divided image based on the image, and
generates, based on the region divided image and the measurement area cursor generation rule, the measurement area cursor to be disposed in the structure by applying the measurement area cursor generation rule to a region element included in the region divided image.

3. The measurement system according to claim 2, wherein
the processor
acquires a sample image as the image,
generates the region divided image based on the sample image,
acquires the measurement area cursor generation rule set based on the region divided image of the sample image,
acquires a measurement target image of the structure of the semiconductor device captured by the microscope during measurement,
generates the region divided image based on the measurement target image,
generates the measurement area cursor to be disposed with respect to the structure based on the region divided image of the measurement target image and the measurement area cursor generation rule,
disposes the measurement area cursor with respect to the structure in the measurement target image, and
performs the measurement related to the structure using a portion of the measurement target image in the measurement area cursor.

4. The measurement system according to claim 1, wherein
the structure has, as a three-dimensional structure, at least a lower layer pattern and an upper layer pattern overlapping the lower layer pattern, and
the processor measures an overlay deviation amount in a set of the lower layer pattern and the upper layer pattern as a measurement target.

5. The measurement system according to claim 2, wherein
the processor provides a user with a screen displaying the region divided image and the measurement area cursor generation rule, and sets the measurement area cursor generation rule based on an operation of checking the region divided image by the user on the screen.

6. The measurement system according to claim 2, wherein
the structure has, as a three-dimensional structure, at least a lower layer pattern and an upper r layer pattern overlapping the lower layer pattern,
the region divided image has a region type for each region element,
the region type has at least the lower layer pattern, the upper layer pattern, and a background region, and
the measurement area cursor generation rule has the region type of the region element for generating the measurement area cursor to be applied to the structure as a measurement target.

7. The measurement system according to claim 6, wherein
the measurement area cursor generation rule includes reference coordinate information of the region element of the region type for generating the measurement area cursor and a correction value indicating a relative relationship from the reference coordinate information.

8. The measurement system according to claim 7, wherein
the measurement area cursor generation rule has a maximum value or a minimum value in a designated direction in a designated region element as the reference coordinate information, has a correction value in the designated direction as the correction value, and is capable of designating coordinate information selected from coordinate information of the upper layer pattern and coordinate information of the lower layer pattern as the reference coordinate information for generating the measurement area cursor to be applied to the lower layer pattern.

9. The measurement system according to claim 1, wherein
the measurement area cursor generation rule is attached with a measurement area cursor possibility determination rule for determining whether measurement is possible by generating the measurement area cursor with respect to the structure, and
the processor does not generate the measurement area cursor with respect to the structure when it is determined as no based on the measurement area cursor possibility determination rule.

10. The measurement system according to claim 9, wherein
the measurement area cursor possibility determination rule includes a condition that the measurement area cursor is not to be generated in a case where a width of the measurement area cursor is less than or is less than or equal to a designated width when the measurement area cursor is to be generated with respect to the structure based on the measurement area cursor generation rule.

11. The measurement system according to claim 3, wherein
the processor
trains a learning model that generates the region divided image based on the sample image,
sets the measurement area cursor generation rule based on the region divided image generated by the learning model, and
generates the region divided image by the learning model based on the measurement target image during the measurement, and
the learning is unsupervised machine learning that does not use, as an input, training data in which a label indicating a region type is assigned to a pixel of the image, or supervised machine learning that uses the training data as an input.

12. The measurement system according to claim 3, wherein
the measurement area cursor generation rule is set to generate the measurement area cursor by rule-based program processing, and
the processor generates the measurement area cursor by the rule-based program processing based on the region divided image and the measurement area cursor generation rule.

13. The measurement system according to claim 2, wherein
an image type of the image includes an SE image of the structure of the semiconductor device captured by detecting a secondary electron (SE) by the microscope, a BSE image of the structure of the semiconductor device captured by detecting a backscattered electron (BSE) by the microscope, and a composite image obtained by combining the SE image and the BSE image, and
the processor
generates the region divided image based on the composite image as the image having a designated image type, and
disposes the measurement area cursor with respect to the structure in the image having the designated image type.

14. A computer in a measurement system for a semiconductor device including a microscope and a processor, the computer comprising:
the processor, wherein
the processor
acquires an image of a structure of the semiconductor device captured by the microscope,
acquires a measurement area cursor generation rule related to the structure,
generates a measurement area cursor to be disposed with respect to the structure based on the image and the measurement area cursor generation rule,
disposes the measurement area cursor with respect to the structure in the image, and
performs measurement related to the structure using a portion of the image in the measurement area cursor.

15. A measurement method to be executed by a computer including a processor measurement system for a semiconductor device including a microscope and the computer, the measurement method comprising, as steps to be executed by the computer:
a step of acquiring an image of a structure of the semiconductor device captured by the microscope;
a step of acquiring a measurement area cursor generation rule related to the structure;
a step of generating a measurement area cursor to be disposed with respect to the structure based on the image and the measurement area cursor generation rule;
a step of disposing the measurement area cursor with respect to the structure in the image; and
a step of performing measurement related to the structure using a portion of the image in the measurement area cursor.
